(19) United States
(12) Patent Application Publication
(10) Pub. No.: US 2025/0006595 A1
(43) Pub. Date: Jan. 2, 2025

(54) SEMICONDUCTOR DEVICE AND METHOD OF MANUFACTURING THE SAME

(71) Applicant: Sumitomo Electric Device Innovations, Inc., Yokohama-shi (JP)

(72) Inventor: Yuya TSUTSUMI, Yokohama-shi (JP)

(73) Assignee: Sumitomo Electric Device Innovations, Inc., Yokohama-shi (JP)

(21) Appl. No.: 18/746,698

(22) Filed: Jun. 18, 2024

(30) Foreign Application Priority Data
Jun. 30, 2023 (JP) 2023-108428

(51) Int. Cl. H01L 23/482; H01L 27/088; H01L 29/417; H01L 29/423

(52) U.S. Cl. CPC H01L 23/4824; H01L 27/088; H01L 29/41758; H01L 29/42364; H01L 29/4238

(57) ABSTRACT

A semiconductor device includes a substrate, a first unit FET including first source, first drain, and first gate electrodes, a second unit FET including second source, second drain, and second gate electrodes, a first source wiring electrically contacting the first source electrode, a gate bus bar electrically connected to the first gate electrode, and interposing the first gate electrode between the gate bus bar and the second gate electrode, and a gate wiring provided above the first source electrode in non-contact with the first source electrode, and electrically connecting the gate bus bar and the second gate electrode, wherein a maximum width in a first direction of a region where the first source wiring contacts the first source electrode is ½ times or more a maximum width in the first direction of a region where the first source wiring overlaps the first source electrode.

### CROSS REFERENCE TO RELATED APPLICATIONS

This application claims priority based on Japanese Patent Application No. 2023-108428, filed on Jun. 30, 2023, and the entire contents of the Japanese patent applications are incorporated herein by reference.

### FIELD

A certain aspect of the embodiments is related to a semiconductor device and a method for manufacturing the same.

### BACKGROUND

In a field effect transistor (FET) having a finger-shaped source electrode, a finger-shaped gate electrode, and a finger-shaped drain electrode, it is known that a plurality of unit FETs each having the source electrode, the gate electrode, and the drain electrode are arranged in an extending direction of the electrodes (for example, Patent Document 1: Japanese Laid-Open Patent Application No. 2002-299351, and Patent Document 2: U.S. Pat. No. 9,786,660).

### SUMMARY

A semiconductor device according to the present disclosure includes: a substrate; a first unit FET that is provided on the substrate, and includes a first source electrode extending in a first direction, a first drain electrode extending in the first direction, and a first gate electrode extending in the first direction and provided between the first source electrode and the first drain electrode in a second direction intersecting the first direction; a second unit FET that is provided on the substrate in the first direction with respect to the first unit FET, and includes a second source electrode extending in the first direction, a second drain electrode extending in the first direction, and a second gate electrode extending in the first direction and provided between the second source electrode and the second drain electrode in the second direction; a first source wiring that extends in the first direction, is provided on the first source electrode, and is in electrical contact with the first source electrode; a gate bus bar that is electrically connected to the first gate electrode, and is provided so as to interpose the first gate electrode between the gate bus bar and the second gate electrode in the first direction; and a gate wiring that is provided above the first source electrode in non-contact with the first source electrode, interposes the first source wiring between the gate wiring and the first drain electrode in the second direction, extends in the first direction, and electrically connects the gate bus bar and the second gate electrode to each other; wherein a maximum width in the first direction of a region where the first source wiring is in contact with the first source electrode is ½ times or more a maximum width in the first direction of a region where the first source wiring overlaps the first source electrode when viewed from a thickness direction of the substrate.

A method of manufacturing a semiconductor device according to the present disclosure includes: forming a first unit FET and a second unit FET on a substrate, the first unit FET including: a first source electrode extending in a first direction; a first drain electrode extending in the first direction; and a first gate electrode extending in the first direction and provided between the first source electrode and the first drain electrode in a second direction intersecting the first direction, the second unit FET including: a second source electrode extending in the first direction, a second drain electrode extending in the first direction, and a second gate electrode extending in the first direction and provided between the second source electrode and the second drain electrode in the second direction, the second unit FET being positioned in the first direction with respect to the first unit FET; simultaneously forming a first source wiring extending in the first direction, provided on the first source electrode, and being in electrical contact with the first source electrode, a second source wiring extending in the first direction, provided on the second source electrode, and being in electrical contact with the second source electrode, and a first drain wiring extending in the first direction, provided on the first drain electrode, and being in electrical contact with the first drain electrode; and forming a gate wiring that is provided above the first source electrode in non-contact with the first source electrode, interposes the first source wiring between the gate wiring and the first drain electrode in the second direction, extends in the first direction, and electrically connects a gate bus bar and the second gate electrode to each other.

### BRIEF DESCRIPTION OF DRAWINGS

FIG. 1 is a plan view of a semiconductor device according to a first embodiment.

FIG. 2 is a cross-sectional view taken along a line A-A in FIG. 1.

FIG. 3 is a cross-sectional view taken along a line B-B in FIG. 1.

FIG. 4 is a cross-sectional view taken along a line C-C in FIG. 1.

FIG. 5 is a cross-sectional view taken along a line D-D in FIG. 1.

FIG. 6 is a cross-sectional view taken along a line E-E in FIG. 1.

FIG. 7A is a cross-sectional view illustrating a method for manufacturing the semiconductor device according to the first embodiment.

FIG. 7B is a cross-sectional view illustrating the method for manufacturing the semiconductor device according to the first embodiment.

FIG. 8A is a cross-sectional view illustrating the method for manufacturing the semiconductor device according to the first embodiment.

FIG. 8B is a cross-sectional view illustrating the method for manufacturing the semiconductor device according to the first embodiment.

FIG. 9A is a cross-sectional view illustrating the method for manufacturing the semiconductor device according to the first embodiment.

FIG. 9B is a cross-sectional view illustrating the method for manufacturing the semiconductor device according to the first embodiment.

FIG. 10A is a cross-sectional view illustrating the method for manufacturing the semiconductor device according to the first embodiment.

FIG. 10B is a cross-sectional view illustrating the method for manufacturing the semiconductor device according to the first embodiment.

FIG. 11A is a cross-sectional view illustrating the method for manufacturing the semiconductor device according to the first embodiment.

FIG. 11B is a cross-sectional view illustrating the method for manufacturing the semiconductor device according to the first embodiment.

FIG. 12A is a cross-sectional view illustrating the method for manufacturing the semiconductor device according to the first embodiment.

FIG. 12B is a cross-sectional view illustrating the method for manufacturing the semiconductor device according to the first embodiment.

FIG. 13A is a cross-sectional view illustrating the method for manufacturing the semiconductor device according to the first embodiment.

FIG. 13B is a cross-sectional view illustrating the method for manufacturing the semiconductor device according to the first embodiment.

FIG. 14A is a cross-sectional view illustrating the method for manufacturing the semiconductor device according to the first embodiment.

FIG. 14B is a cross-sectional view illustrating the method for manufacturing the semiconductor device according to the first embodiment.

FIG. 15 is a cross-sectional view of a semiconductor device according to a first comparative example.

FIG. 16 is a cross-sectional view of a semiconductor device according to a second comparative example.

FIG. 17 is a cross-sectional view of a semiconductor device according to a first modification of the first embodiment.

FIG. 18 is a cross-sectional view of the semiconductor device according to the first modification of the first embodiment.

FIG. 19 is a plan view of a semiconductor device according to a second modification of the first embodiment.

FIG. 20 is a cross-sectional view taken along a line A-A in FIG. 19.

FIG. 21 is a cross-sectional view taken along a line B-B in FIG. 19.

FIG. 22 is a plan view of a semiconductor device according to a third modification of the first embodiment.

FIG. 23 is a cross-sectional view taken along a line A-A in FIG. 22.

FIG. 24 is a cross-sectional view of a semiconductor device according to a fourth modification of the first embodiment.

FIG. 25 is a cross-sectional view of the semiconductor device according to the fourth modification of the first embodiment.

FIG. 26 is a cross-sectional view of a semiconductor device according to a fifth modification of the first embodiment.

FIG. 27 is a plan view of a semiconductor device according to a sixth modification of the first embodiment.

FIG. 28 is a sectional view taken along a line A-A of FIG. 27.

FIG. 29 is a plan view of a semiconductor device according to a second embodiment.

FIG. 30 is a sectional view taken along a line A-A of FIG. 29.

FIG. 31 is a cross-sectional view illustrating a method of manufacturing the semiconductor device according to the second embodiment.

FIG. 32 is a cross-sectional view illustrating the method of manufacturing the semiconductor device according to the second embodiment.

FIG. 33 is a cross-sectional view illustrating the method of manufacturing the semiconductor device according to the second embodiment.

FIG. 34 is a cross-sectional view illustrating the method of manufacturing the semiconductor device according to the second embodiment.

FIG. 35 is a cross-sectional view illustrating the method of manufacturing the semiconductor device according to the second embodiment.

FIG. 36 is a plan view of a semiconductor device according to a first modification of the second embodiment.

FIG. 37 is a cross-sectional view taken along a line A-A of FIG. 36.

FIG. 38 is a cross-sectional view taken along a line B-B of FIG. 36.

FIG. 39 is a plan view of a semiconductor device according to a third embodiment.

FIG. 40 is a cross-sectional view taken along a line A-A of FIG. 39.

FIG. 41 is a plan view of a semiconductor device according to a first modification of the third embodiment.

FIG. 42 is a plan view of a semiconductor device according to a second modification of the third embodiment.

FIG. 43 is a plan view of a semiconductor device according to a third modification of the third embodiment.

FIG. 44 is a plan view of a semiconductor device according to a fourth embodiment.

### DETAILED DESCRIPTION OF EMBODIMENTS

In Patent Documents 1 and 2, the width of the gate electrode in the unit FET can be shortened by arranging a plurality of unit FETs in the extending direction of the electrodes. Therefore, the gate resistance can be suppressed. However, a gate wiring electrically connecting a gate pad to the gate electrode away from the gate pad is provided above the unit FET. This increases a parasitic capacitance between the gate wiring and a drain electrode, and deteriorates the characteristics such as the gain. On the other hand, when the gate wiring is arranged so as not to overlap the unit FET, the semiconductor device is increased in size.

The present disclosure has been made in view of the above problems, and an object thereof is to suppress deterioration in characteristics and to reduce the size.

### Details of Embodiments of the Present Disclosure

First, the contents of the embodiments of this disclosure are listed and explained.

(1) A semiconductor device according to the present disclosure includes: a substrate; a first unit FET that is provided on the substrate, and includes a first source electrode extending in a first direction, a first drain electrode extending in the first direction, and a first gate electrode extending in the first direction and provided between the first source electrode and the first drain electrode in a second direction intersecting the first direction; a second unit FET that is provided on the substrate in the first direction with respect to the first unit FET, and includes a second source electrode extending in the first direction, a second drain electrode extending in the first direction, and a second gate electrode extending in the first direction and provided between the second source electrode and the second drain electrode in the second direction; a first source wiring that extends in the first direction, is provided on the first source electrode, and is in electrical contact with the first source electrode; a gate bus bar that is electrically connected to the first gate electrode, and is provided so as to interpose the first gate electrode between the gate bus bar and the second gate electrode in the first direction; and a gate wiring that is provided above the first source electrode in non-contact with the first source electrode, interposes the first source wiring between the gate wiring and the first drain electrode in the second direction, extends in the first direction, and electrically connects the gate bus bar and the second gate electrode to each other. A maximum width in the first direction of a region where the first source wiring is in contact with the first source electrode is ½ times or more a maximum width in the first direction of a region where the first source wiring overlaps the first source electrode when viewed from a thickness direction of the substrate. This makes it possible to suppress the gate/drain capacitance and to suppress the deterioration of the characteristics. In addition, the semiconductor device can be downsized.

(2) In the above (1), a height of an upper surface of the gate wiring from an upper surface of the substrate may be smaller than a height of an upper surface of the first source wiring from the upper surface of the substrate. This makes it possible to further suppress the gate/drain capacitance.

(3) In the above (1) or (2), the semiconductor device further may include a first drain wiring that extends in the first direction, is provided on the first drain electrode, and is in electrical contact with the first drain electrode. A thickness of the first source wiring may be equal to or less than a thickness of the first drain wiring. This can reduce the number of manufacturing steps.

(4) In any one of the above (1) to (3), the semiconductor device further may include a second source wiring that extends in the first direction, is provided on the second source electrode, and is in electrical contact with the second source electrode. A thickness of the first source wiring may be equal to a thickness of the second source wiring. This can reduce the number of manufacturing steps.

(5) In any one of the above (1) to (4), the semiconductor device further may include: an inorganic insulating film provided on the first source electrode; and an organic insulating film or an air gap provided between the inorganic insulating film and the gate wiring. This makes it possible to reduce the gate-source capacitance and suppress the deterioration of the characteristics.

(6) In the above (5), in a first portion which is a part in the first direction of a region where the gate wiring overlaps with the first source electrode in the first direction when viewed from the thickness direction of the substrate, the gate wiring may be in contact with the inorganic insulating film without interposing the organic insulating film or the air gap therebetween, and in second portions which interpose the first portion in the first direction of the region, the gate wiring and the inorganic insulating film may interpose the organic insulating film or the air gap. This makes it possible to stabilize the shape of the gate wiring.

(7) In any one of the above (1) to (6), the semiconductor device further may include: a second source wiring that extends in the first direction, is provided on the second source electrode, and is in electrical contact with the second source electrode; and a first connection wiring that extends in the second direction, is interposed between the first source electrode and the second source electrode in the first direction, and electrically connects the gate wiring and the second gate electrode to each other. The first source wiring may intersect the first connection wiring in a non-contact manner and be connected to the second source wiring. This makes it possible to further suppress the gate/drain capacitance.

(8) In any one of the above (1) to (7), the semiconductor device further may include: a third unit FET that is provided on the substrate, and includes the first source electrode, a third drain electrode extending in the first direction and interposing the first source electrode between the third drain electrode and the first drain electrode in the second direction, and a third gate electrode extending in the first direction and provided between the first source electrode and the third drain electrode in the second direction; a fourth unit FET that is provided on the substrate in the first direction with respect to the third unit FET, and includes the second source electrode, a fourth drain electrode extending in the first direction and interposing the second source electrode between the fourth drain electrode and the second drain electrode in the second direction, and a fourth gate electrode extending in the first direction and provided between the second source electrode and the fourth drain electrode in the second direction; and a third source wiring that extends in the first direction, is provided on the first source electrode, interposes the gate wiring between the third source wiring and the first source wiring in the second direction, and is in electrical contact with the first source electrode. A maximum width in the first direction of a region where the third source wiring is in contact with the first source electrode may be ½ times or more a maximum width in the first direction of a region where the third source wiring overlaps the first source electrode when viewed from the thickness direction of the substrate. This enables the semiconductor device to be downsized.

(9) In the above (8), the semiconductor device further may include a first connection wiring that is interposed between the first source electrode and the second source electrode in the first direction and electrically connects the second gate electrode and the fourth gate electrode to each other. An end of the gate wiring may be connected to a central portion of the first connection wiring in the second direction. This allows a gate potential to be supplied to the second gate electrode and the fourth gate electrode.

(10) In the above (8) or (9), the semiconductor device further may include a guard metal layer that is provided above the gate wiring in non-contact with the gate wiring, and connects the first source wiring and the third source wiring to each other. This makes it possible to further suppress the gate/drain capacitance.

(11) In any one of the above (1) to (10), the semiconductor device further may include: a fifth unit FET that is provided on the substrate, and includes a third source electrode extending in the first direction and interposing the first drain electrode between the third source electrode and the first source electrode in the second direction, the first drain electrode, and a fifth gate electrode extending in the first direction and provided between the third source electrode and the first drain electrode in the second direction; a fourth source wiring that extends in the first direction, is provided on the third source electrode, and is in electrical contact with the third source electrode; and a second connection wiring that is provided between the first drain electrode and the gate bus bar in the first direction and electrically connects the first source wiring and the fourth source wiring to each other.

(12) A method of manufacturing a semiconductor device according to the present disclosure includes: forming a first unit FET and a second unit FET on a substrate, the first unit FET including: a first source electrode extending in a first direction; a first drain electrode extending in the first direction; and a first gate electrode extending in the first direction and provided between the first source electrode and the first drain electrode in a second direction intersecting the first direction, the second unit FET including: a second source electrode extending in the first direction, a second drain electrode extending in the first direction, and a second gate electrode extending in the first direction and provided between the second source electrode and the second drain electrode in the second direction, the second unit FET being positioned in the first direction with respect to the first unit FET; simultaneously forming a first source wiring extending in the first direction, provided on the first source electrode, and being in electrical contact with the first source electrode, a second source wiring extending in the first direction, provided on the second source electrode, and being in electrical contact with the second source electrode, and a first drain wiring extending in the first direction, provided on the first drain electrode, and being in electrical contact with the first drain electrode; and forming a gate wiring that is provided above the first source electrode in non-contact with the first source electrode, interposes the first source wiring between the gate wiring and the first drain electrode in the second direction, extends in the first direction, and electrically connects a gate bus bar and the second gate electrode to each other. This makes it possible to suppress deterioration of the characteristics. In addition, the semiconductor device can be downsized. Furthermore, the manufacturing process can be reduced.

Specific examples of a semiconductor device and a method for manufacturing the same according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

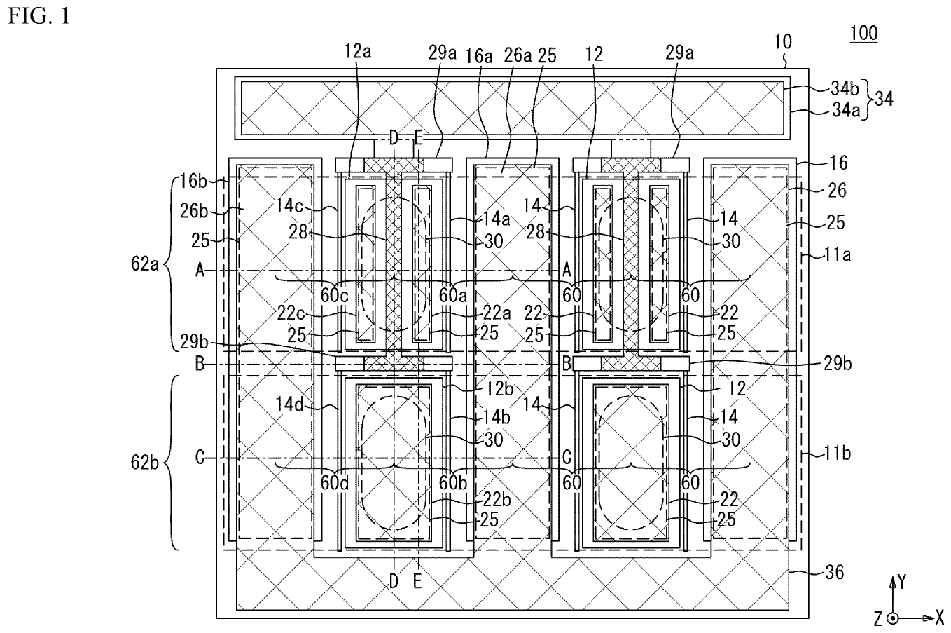

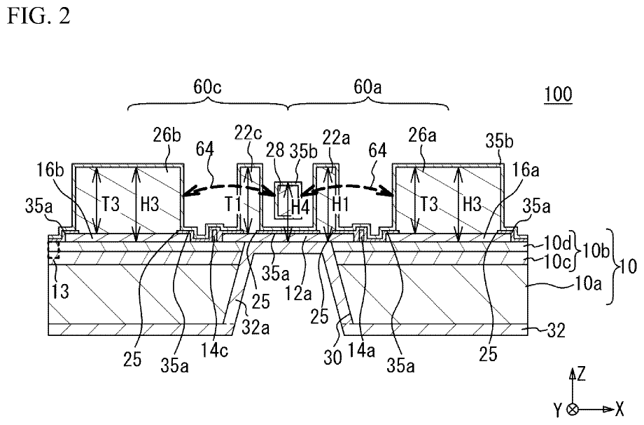

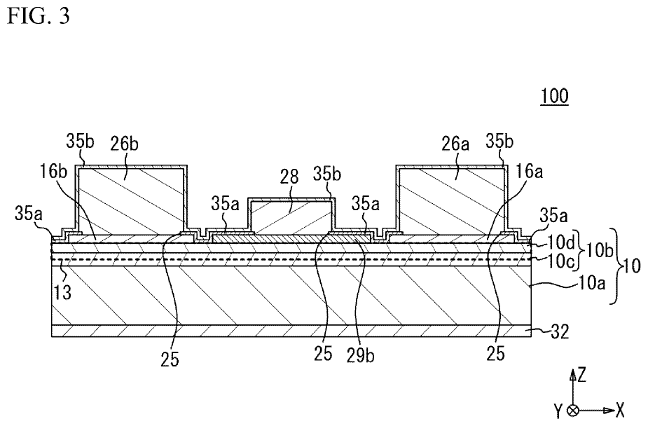

The following description will be made by taking, as an example, a semiconductor device used in an amplifier for amplifying a high frequency signal from 0.5 GHz to 10 GHz in a base station of mobile communication. FIG. 1 is a plan view of a semiconductor device according to a first embodiment. FIGS. 2 to 6 are cross-sectional views taken along lines A-A, B-B, C-C, D-D, and E-E in FIG. 1, respectively. A thickness direction of a substrate 10 is a Z direction, an extending direction of respective finger-shaped electrodes is a Y direction (first direction), and an arrangement direction of respective electrodes is an X direction (second direction intersecting the first direction).

In each of the drawings, source electrodes 12, gate electrodes 14, drain electrodes 16, source wirings 22, drain wirings 26, and unit FETs 60 indicate general elements. Source electrodes 12a and 12b, gate electrodes 14a to 14d, drain electrodes 16a and 16b, source wirings 22a to 22c, drain wirings 26a and 26b, and unit FETs 60a to 60d indicate specific elements included in the general elements. In the following description, the unit FETs 60a to 60d will be mainly described using the source electrodes 12a and 12b, the gate electrodes 14a to 14d, the drain electrodes 16a and 16b, the source wirings 22a to 22c, and the drain wirings 26a and 26b.

As illustrated in FIGS. 1 to 6, in a semiconductor device 100 of the first embodiment, the substrate 10 includes a substrate 10a and a semiconductor layer 10b provided on the substrate 10a. The semiconductor layer 10b includes, for example, a channel layer 10c and a barrier layer 10d. In an XY plane parallel to the X direction and the Y direction, a region of the semiconductor layer 10b inactivated by ion implantation or the like is an inactive region 13, and regions not inactivated are active regions 11a and 11b.

The active regions 11a and 11b are arranged in the Y direction and extend in the X direction. The active region 11a is provided with an FET group 62a including a plurality of unit FETs 60 arranged in the X direction. The active region 11b is provided with an FET group 62b including the plurality of unit FETs 60 arranged in the X direction.

In the FET group 62a, each of the source electrode 12a (first source electrode), the gate electrode 14a (first gate electrode), the gate electrode 14c (third gate electrode), the drain electrode 16a (first drain electrode) and the drain electrode 16b (third drain electrode) extends in the Y direction. In the X direction, the gate electrodes 14a and 14c are provided with the source electrode 12a interposed therebetween. In the X direction, the gate electrode 14a is provided between the source electrode 12a and the drain electrode 16a, and the gate electrode 14c is provided between the source electrode 12a and the drain electrode 16b. The unit FET 60a (first unit FET) includes the source electrode 12a, the gate electrode 14a, and the drain electrode 16a. The unit FET 60c (third unit FET) includes the source electrode 12a, the gate electrode 14c, and the drain electrode 16b. The source wiring 22a (first source wiring) and the source wiring 22c (third source wiring) are provided on the source electrode 12a and are electrically in contact with the source electrode 12a. The source wirings 22a and 22c extend in the Y direction and are arranged in the X direction.

In the FET group 62b, each of the source electrode 12b (second source electrode), the gate electrode 14b (second gate electrode), the gate electrode 14d (fourth gate electrode), the drain electrode 16a (second drain electrode) and the drain electrode 16b (fourth drain electrode) extends in the Y direction. In the X direction, the gate electrodes 14b and 14d are provided with the source electrode 12b interposed therebetween. In the X direction, the gate electrode 14b is provided between the source electrode 12b and the drain electrode 16a, and the gate electrode 14d is provided between the source electrode 12b and the drain electrode 16b. The unit FET 60b (second unit FET) includes the source electrode 12b, the gate electrode 14b, and the drain electrode 16a. The unit FET 60d (fourth unit FET) includes the source electrode 12b, the gate electrode 14d, and the drain electrode 16b. The source wiring 22b (second source wiring) is provided on the source electrode 12b and is electrically in contact with the source electrode 12b. The source wiring 22b extends in the Y direction.

The drain electrodes 16a of the FET group 62a and the drain electrodes 16a of the FET group 62b are integrally and continuously provided, and the drain electrodes 16b of the FET group 62a and the drain electrodes 16b of the FET group 62b are integrally and continuously provided. The drain wiring 26a (first drain wiring) and the drain wiring 26b (second drain wiring) are provided on the drain electrodes 16a and 16b, respectively, are electrically contact the drain electrodes 16a and 16b, respectively. The drain wirings 26a and 26b extend in the Y direction. A drain bus bar 36 is provided so as to interpose the FET group 62b between the drain bus bar 36 and the FET group 62a in the Y direction. The − ends of the drain electrodes 16a and 16b in the Y direction are connected to the drain bus bar 36.

A gate bus bar 34 is provided so as to interpose the FET group 62a between the gate bus bar 34 and the FET group 62b in the Y direction. The gate bus bar 34 includes a gate metal layer 34a and a pad metal layer 34b provided on the gate metal layer 34a. Connection wirings 29a are provided between the gate bus bar 34 and the FET group 62a in the Y direction. The connection wiring 29a extends in the X direction and connects the + end of the gate electrode 14a in the Y direction and the + end of the gate electrode 14c in the Y direction. The gate bus bar 34 and the gate electrodes 14a and 14c are electrically connected and short-circuited to each other through the connection wiring 29a.

Connection wirings 29b are provided between the FET groups 62a and 62b in the Y direction. The connection wiring 29b (first connection wiring) extends in the X direction and connects the + end of the gate electrode 14b in the X direction and the +end of the gate electrode 14d in the X direction. A gate wiring 28 is provided above the source electrode 12a so as not to be electrically in contact with the source electrode 12a, and extends in the Y direction. The connection wirings 29a and 29b are electrically connected to each other by the gate wiring 28. The gate bus bar 34 and the gate electrodes 14b and 14d are electrically connected and short-circuited via the connection wiring 29a, the gate wiring 28 and the connection wiring 29b.

An insulating film 35a is formed on the substrate 10 so as to cover the source electrodes 12a and 12b, the gate electrodes 14a to 14d, the drain electrodes 16a and 16b, and the connection wirings 29a and 29b. The insulating film 35a has openings 25 through which the upper surfaces of the source electrodes 12a and 12b, the drain electrodes 16a and 16b, and the connection wirings 29a and 29b are exposed. The source wirings 22a and 22c provided on the source electrode 12a are electrically in contact with the source electrode 12a through the openings 25. The source wiring 22b and the drain wiring 26a and 26b provided on the source electrode 12b and the drain electrodes 16a and 16b are in electrical contact with the source electrode 12b and the drain electrodes 16a and 16b through the openings 25, respectively. The gate wiring 28 is in electrical contact with the connection wirings 29a and 29b through the openings 25.

An insulating film 35b is provided on the source wirings 22a to 22c, the drain wirings 26a and 26b, and the gate wiring 28. The insulating film 35b is provided above the source electrode 12a so as to surround the upper surface, the lower surface and the side surfaces of the gate wiring 28. The insulating film 35a, a space 31, and the insulating film 35b are provided between the gate wiring 28 and the source electrode 12a above the source electrode 12a. The space 31 is, for example, an air gap (gas such as air).

Via holes 30 penetrate through the substrate 10 and connect to the source electrodes 12a and 12b. A metal layer 32 is provided on a lower surface of the substrate 10. A metal layer 32a is provided on an inner surface of the via hole 30. Thereby, the metal layer 32 is electrically connected and short-circuited to the source electrodes 12a and 12b through the via holes 30.

A source potential (e.g., a reference potential such as a ground potential) is supplied from the metal layer 32 to the source electrodes 12a and 12b through the metal layer 32a of the via holes 30. A gate potential (for example, a high frequency signal and a gate bias voltage) is supplied from the gate bus bar 34 to the gate electrodes 14a and 14c through the connection wiring 29a. The gate potential is supplied from the gate bus bar 34 to the gate electrodes 14b and 14d through the connection wiring 29a, the gate wiring 28 and the connection wiring 29b. A drain bias voltage is supplied from the drain bus bar 36 to the drain electrodes 16a and 16b. The high frequency signal amplified in each of the unit FETs 60a to 60d is output from the drain electrode 16a or 16b to the drain bus bar 36.

In the unit FETs 60a and 60c, the high frequency signal is input from + ends of the gate electrodes 14a and 14c in the Y direction. In the unit FETs 60b and 60d, the high frequency signal is input from + ends of the gate electrodes 14b and 14d in the Y direction. When the high frequency signals are input to the gate electrodes 14a and 14c from both of + and − ends of the gate electrodes 14a and 14c in the Y direction, the high frequency characteristics of the unit FETs 60a and 60c are deteriorated due to a phase difference or the like. In the first embodiment, since the − ends of the gate electrodes 14a and 14c in the Y direction and the + ends of the gate electrodes 14b and 14d in the Y direction are not connected, the deterioration of the high frequency characteristics of the unit FETs 60a and 60c can be suppressed.

When the semiconductor device 100 is a nitride semiconductor device, the substrate 10a is, for example, a SiC substrate, a silicon substrate, a GaN substrate, or a sapphire substrate. The semiconductor layer 10b includes a nitride semiconductor layer such as a GaN layer, an AlGaN layer and/or an InGaN layer. When the unit FETs 60a to 60d are GaN HEMT (Gallium Nitride High Electron Mobility Transistors), the channel layer 10c is a GaN layer and the barrier layer 10d is an AlGaN layer. When the semiconductor device 100 is, for example, a GaAs semiconductor device, the substrate 10a is, for example, a GaAs substrate. The semiconductor layer 10b includes an arsenide semiconductor layer such as a GaAs layer, an AlGaAs layer and/or an InGaAs layer. The semiconductor device 100 may be a silicon semiconductor device such as LDMOS (Laterally Diffused Metal Oxide Semiconductor).

Each of the source electrodes 12a and 12b and the drain electrodes 16a and 16b is a metal film, and includes, for example, a titanium film and an aluminum film stacked in this order from the substrate 10. The metal film may include, for example, a tantalum film and an aluminum film stacked in this order from the substrate 10. Each of the gate electrodes 14a to 14d, the connection wirings 29a and 29b, and the gate metal layer 34a is a metal film, and includes, for example, a nickel film and a gold film stacked in this order from the substrate 10. The source wirings 22a to 22c, the drain wirings 26a and 26b, and the pad metal layer 34b are, for example, gold layers, copper layers, or aluminum layers. Each of the gate wiring 28 and the metal layer 32 is, for example, a gold layer, a copper layer, or an aluminum layer. The insulating films 35a and 35b are inorganic insulating films such as silicon nitride films.

The lengths of the source electrodes 12a and 12b in the X direction are, for example, 10 μm to 100 μm. The lengths of the drain electrodes 16a and 16b in the X direction are, for example, 1 μm to 50 μm. The lengths of the source wirings 22a and 22c in the X direction are, for example, 1 μm to 50 μm. The length of the source wiring 22b in the X direction is, for example, 5 μm to 100 μm. The length of the gate wiring 28 in the X direction is, for example, 1 μm to 50 μm. The distance between the source electrode 12 and the drain electrode 16 in the X direction is, for example, 1 um to 20 um. The thicknesses of the source wirings 22a to 22c and the drain wirings 26a and 26b are, for example, 1 μm to 10 μm. The thickness of the gate wiring 28 is, for example, 0.5 μm to 5 μm.

### Manufacturing Method of First Embodiment

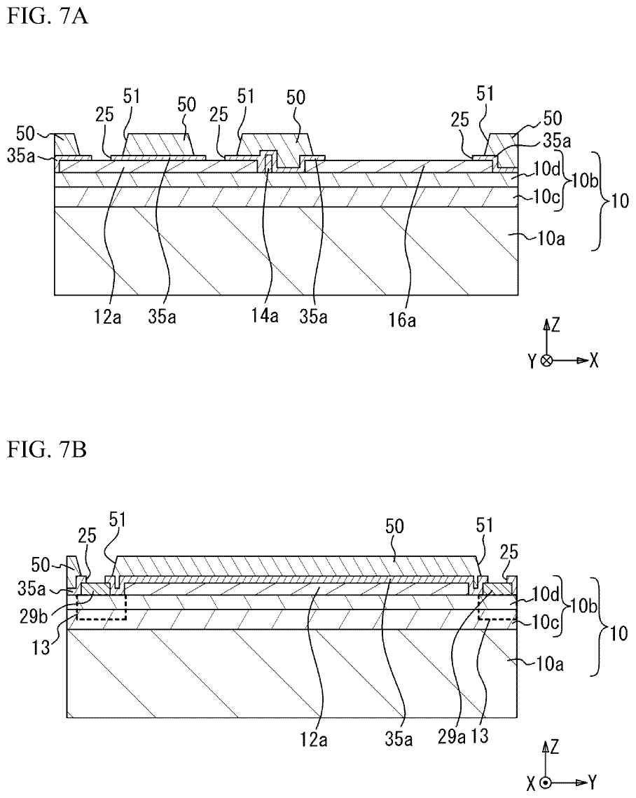

FIGS. 7A to 14B are cross-sectional views illustrating a method of manufacturing a semiconductor device according to the first embodiment. FIGS. 7A, 8A, 9A, 10A, 11A, 12A, 13A and 14A correspond to a part of the A-A cross-section of FIG. 1, and FIGS. 7B, 8B, 9B, 10B, 11B, 12B, 13B and 14B correspond to a part of the E-E cross-section of FIG. 1.

As illustrated in FIGS. 7A and 7B, the source electrodes 12a to 12c, the gate electrodes 14a to 14d, the drain electrodes 16a and 16b, and the connection wirings 29a and 29b are formed on the substrate 10. The insulating film 35a is formed on the substrate 10 so as to cover the source electrodes 12a to 12c, the gate electrodes 14a to 14d, the drain electrodes 16a and 16b, and the connection wirings 29a and 29b. The openings 25 are formed in the insulating film 35a. A mask layer 50 is formed on the insulating film 35a. The mask layer 50 has openings 51 that expose the openings 25. The mask layer 50 is, for example, a photoresist.

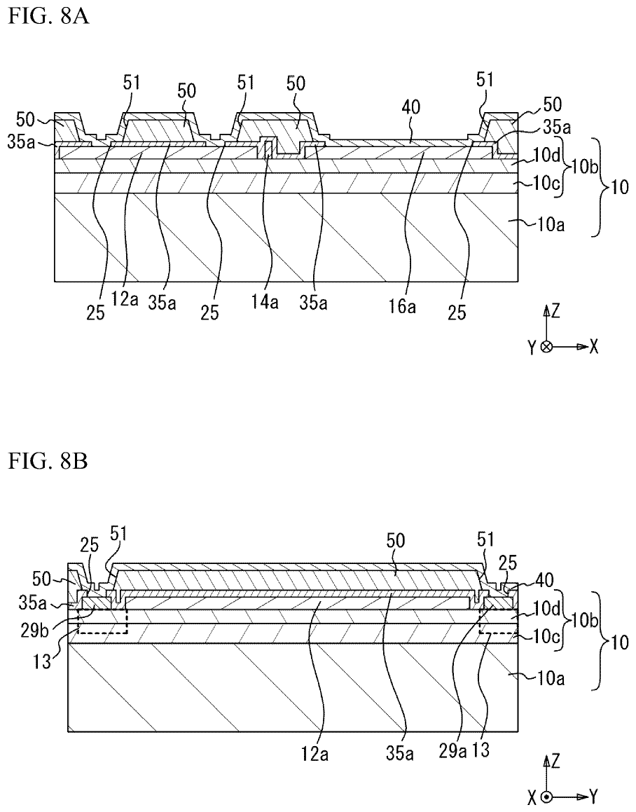

As illustrated in FIGS. 8A and 8B, a seed layer 40 is formed so as to cover the inside of the opening 51 and the mask layer 50. The seed layer 40 is formed on the entire surface of the substrate 10 by, for example, sputtering. The seed layer 40 includes, for example, an adhesion layer and a low resistance layer on the adhesion layer. The low resistance layer is a metal layer made of the same material as, for example, plating layers 41 and 42 described later.

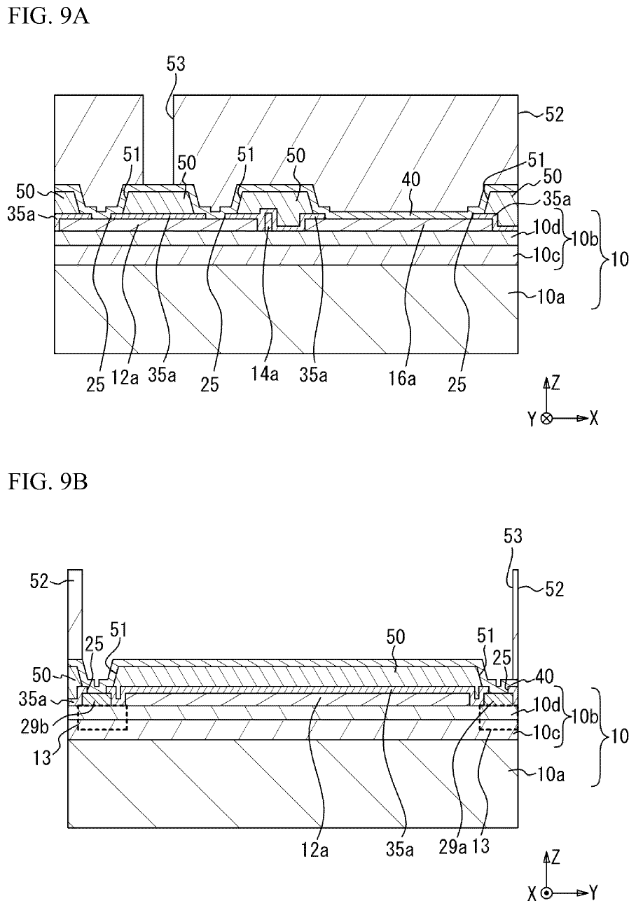

As illustrated in FIGS. 9A and 9B, a mask layer 52 is formed on the seed layer 40. The mask layer 52 has an opening 53 through which the seed layer 40 is exposed on the mask layer 50 on the source electrode 12a. The opening 53 is provided so as to connect the openings 25 on the connection wirings 29a and 29b. The mask layer 52 is, for example, a photoresist.

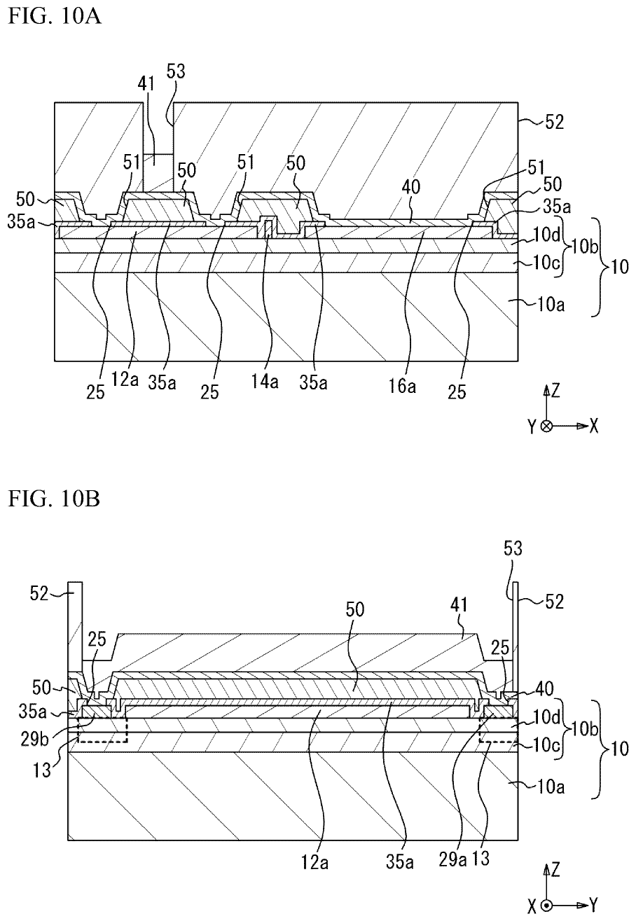

As illustrated in FIGS. 10A and 10B, the plating layer 41 is formed in the opening 53. The plating layer 41 is formed by, for example, electrolytic plating in which a current is supplied through the seed layer 40.

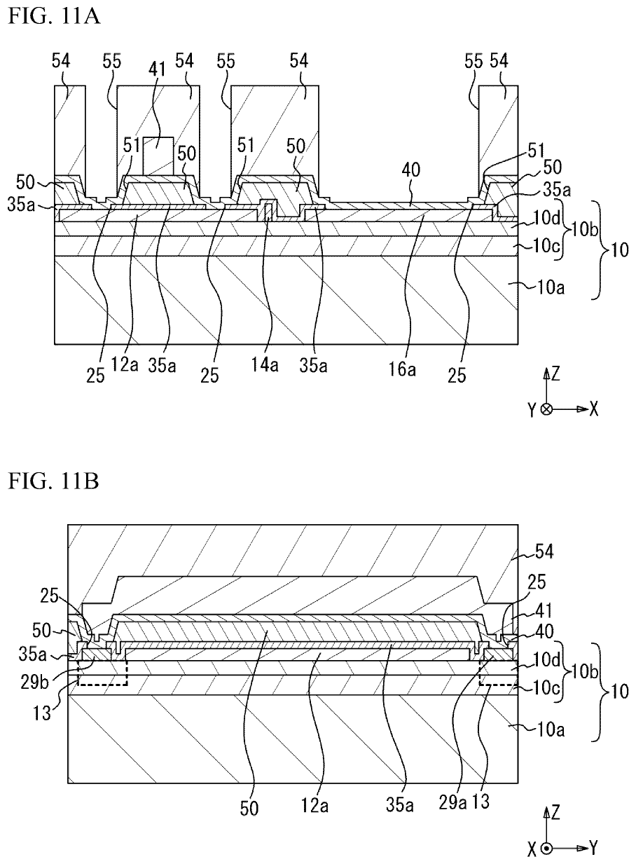

As illustrated in FIGS. 11A and 11B, the mask layer 52 is peeled off. A mask layer 54 is formed on the seed layer 40 and the plating layer 41. The mask layer 54 has openings 55 through which the seed layer 40 is exposed on the openings 25. The mask layer 54 is, for example, a photoresist.

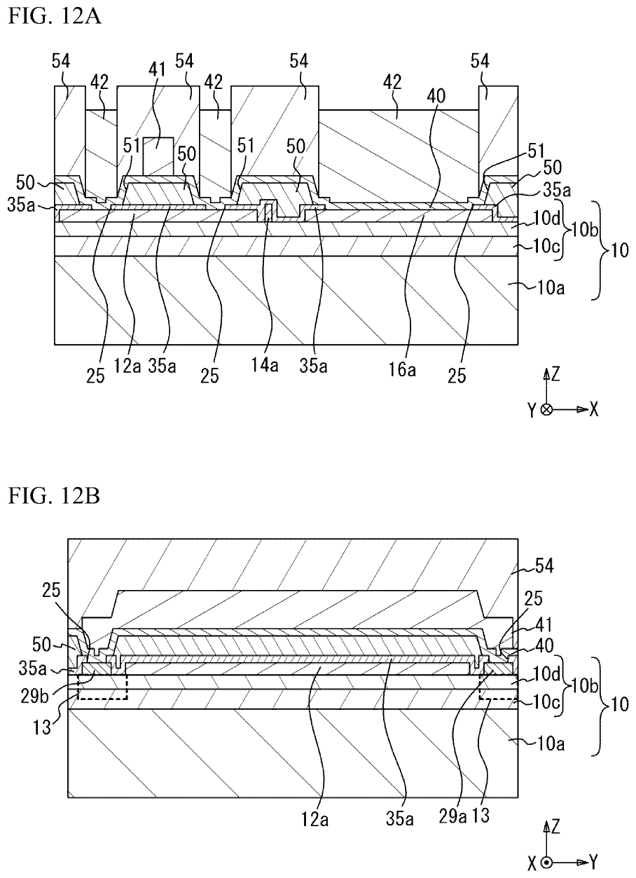

As illustrated in FIGS. 12A and 12B, the plating layer 42 is formed in the opening 55. The plating layer 42 is formed by, for example, electrolytic plating in which a current is supplied through the seed layer 40.

The plating layer 42 may be formed before the plating layer 41 is formed. If the plating layer 42 is formed before the plating layer 41, the mask layer 50 is provided so as to cover the plating layer 42. When the plating layer 42 is thicker than the plating layer 41, it is difficult to provide the mask layer 50 so as to cover the thick plating layer 42. Accordingly, when the plating layer 41 is thinner than the plating layer 42, the plating layer 41 may be formed before the plating layer 42.

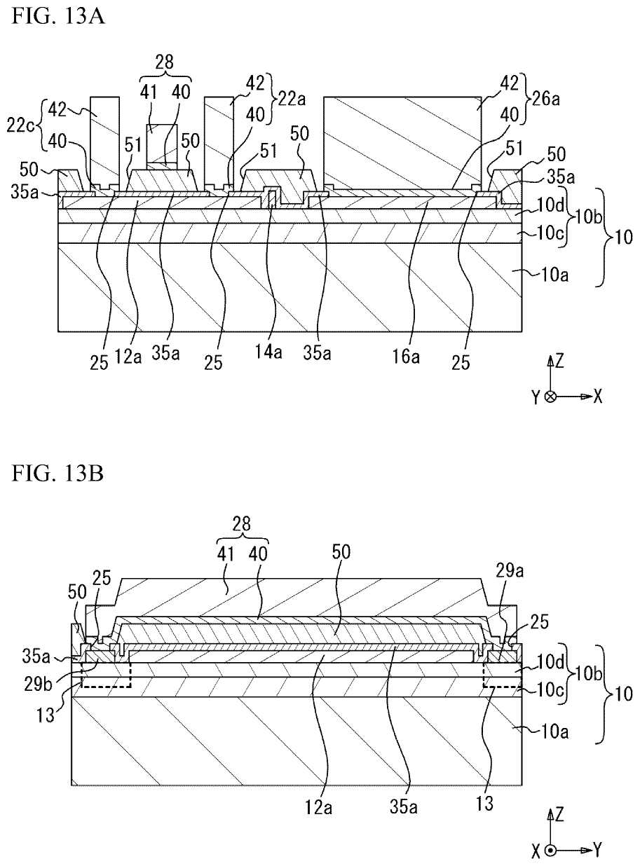

As illustrated in FIGS. 13A and 13B, the mask layer 54 is peeled off. The seed layer 40 is removed using the plating layers 41 and 42 as a mask. Thereby, the gate wiring 28 is formed from the seed layer 40 and the plating layer 41. The source wirings 22a to 22c and the drain wirings 26a and 26b are formed from the seed layer 40 and the plating layer 42. The illustration of the seed layer 40 is omitted in the following description.

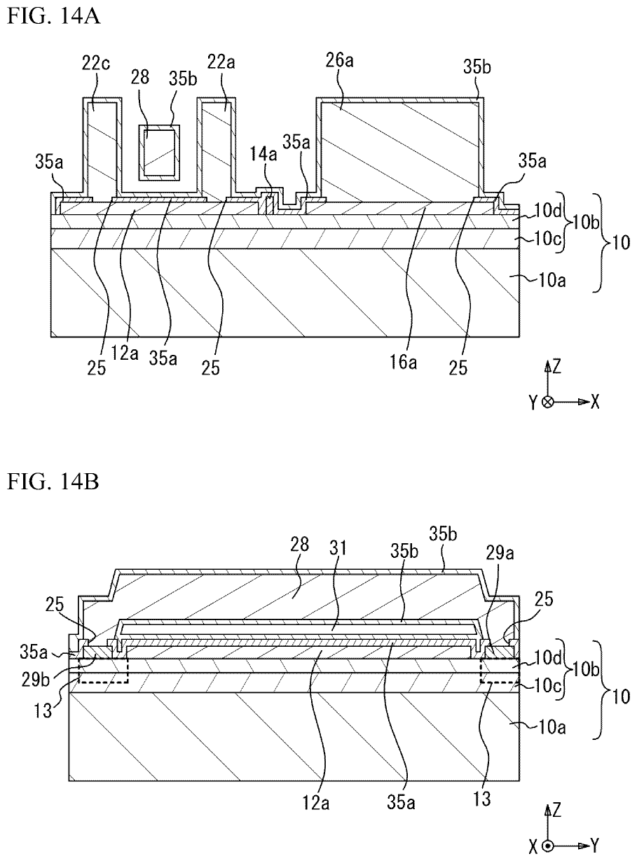

As illustrated in FIGS. 14A and 14B, the mask layer 50 is peeled off. The insulating film 35b is formed so as to cover the source wirings 22a to 22c, the drain wirings 26a and 26b, and the gate wiring 28. Thereby, the space 31 is formed between the gate wiring 28 and the source electrode 12a. As described above, the semiconductor device according to the first embodiment is manufactured.

### First Comparative Example

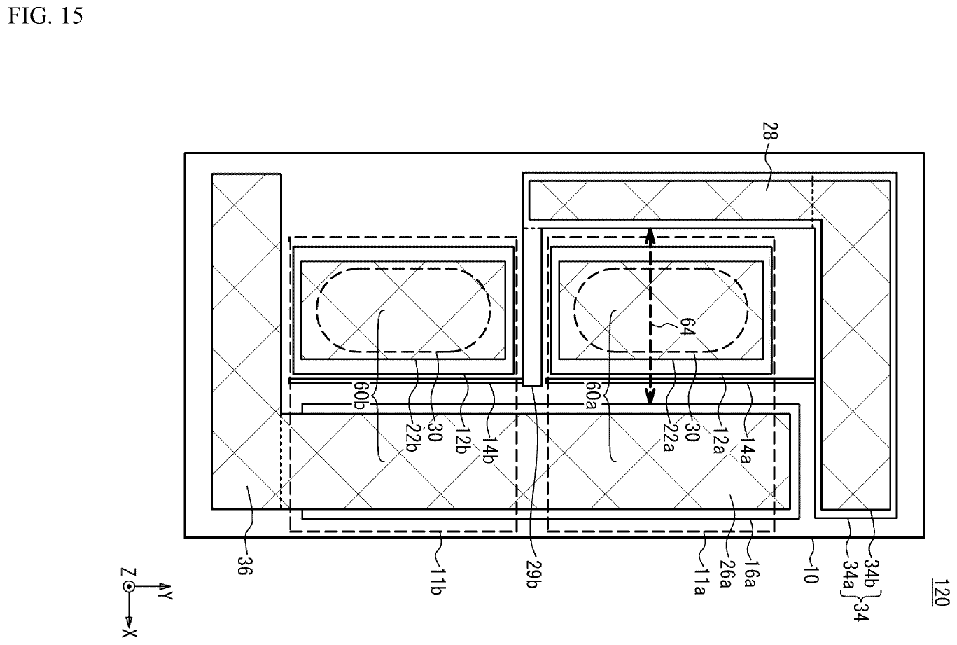

FIG. 15 is a plan view of a semiconductor device according to a first comparative example. As illustrated in FIG. 15, in a semiconductor device 120 of the first comparative example, the unit FETs 60a and 60b are arranged in the Y direction. The gate electrode 14a of the unit FET 60a is directly connected to the gate bus bar 34. The gate electrode 14b of the unit FET 60b is connected to the gate bus bar 34 through the connection wiring 29b and the gate wiring 28. The gate wiring 28 is provided so as to interpose the source electrode 12a between the drain electrode 16a and the gate wiring 28, and the connection wiring 29b is provided between the unit FETs 60a and 60b.

As the width of the gate electrode of the unit FET in the Y direction increases, the gate resistance of the unit FET increases. As the gate resistance increases, a frequency at which a maximum stable gain switches to a maximum available power gain decreases, and the gain at a high frequency decreases. In the first comparative example, the gate widths of the unit FETs 60a and 60b in the Y direction are made shorter. The gate electrode 14b and the gate bus bar 34 are electrically connected to each other through the connection wiring 29b and the gate wiring 28. This can suppress the gate resistance. Therefore, the gain at the high frequency can be improved. Further, when the gate/drain capacitance is increased, a reverse direction power gain S12 is increased. In the first comparative example, the source wiring 22a is provided between the gate wiring 28 and the drain wiring 26a. As a result, the source wiring 22a shields lines of electric force 64 between the gate wiring 28 and the drain wiring 26a. Therefore, since the gate/drain capacitance is suppressed, the reverse direction power gain S12 is reduced, and the gain characteristic of the FET can be improved.

However, the provision of the gate wiring 28 increases the chip size.

### Second Comparative Example

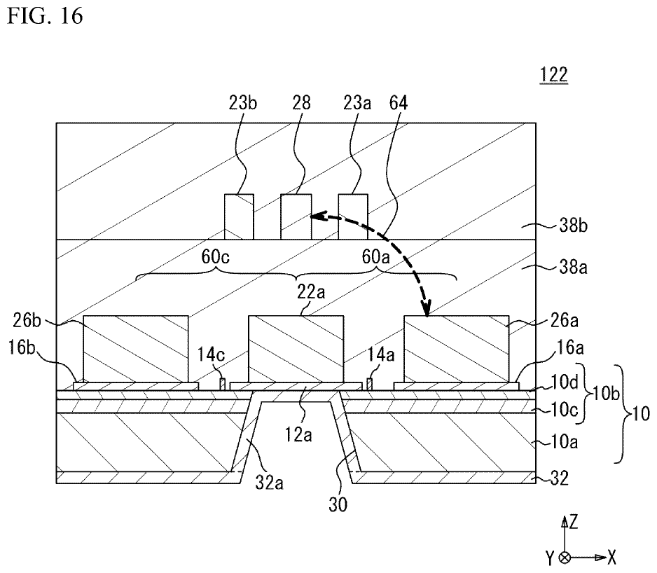

FIG. 16 is a cross-sectional view of a semiconductor device according to a second comparative example. As illustrated in FIG. 16, in a semiconductor device 122 of the second comparative example, the source wiring 22a and the drain wiring 26a and 26b are provided on the source electrode 12a and the drain electrodes 16a and 16b, respectively. An insulating film 38a is provided so as to cover the source wiring 22a and the drain wirings 26a and 26b. Guard metal layers 23a and 23b and the gate wiring 28 are provided on the insulating film 38a. The gate wiring 28 is interposed between the guard metal layers 23a and 23b. The guard metal layers 23a and 23b and the gate wiring 28 are provided so as to overlap the source wiring 22a when viewed from the Z direction. An insulating film 38b is provided so as to cover the guard metal layers 23a and 23b and the gate wiring 28. The other configurations of the second comparative example are the same as those of the first embodiment.

In the second comparative example, since the gate wiring 28 is provided so as to overlap the source wiring 22a, the chip size can be reduced as compared with the first comparative example. The guard metal layers 23a and 23b to which a source potential is supplied are provided so as to interpose the gate wiring 28 therebetween. As a result, the guard metal layers 23a and 23b shield the lines of electric force 64 between the gate wiring 28 and the drain wirings 26a and 26b. Therefore, the gate-drain capacitance is suppressed, the reverse power gain S12 is reduced, and the gain characteristic of the FET can be improved.

However, in order to provide the gate wiring 28 and the guard metal layers 23a and 23b on the insulating film 38a, the insulating film 38a is formed of an organic insulating film, and the upper surface of the insulating film 38a is flattened. In this way, the manufacturing process is increased because a multilayer wiring process is performed. Further, since the insulating films 38a and 38b, which are organic insulating films, become thicker, the stress increases and the warpage of the wafer increases. This reduces the degree of freedom in the selection of the process in the manufacturing process.

### Description of First Embodiment

According to the first embodiment, the gate wiring 28 interposes the source wiring 22a between the gate wiring 28 and the drain electrode 16a in the X direction, and interposes the source wiring 22c between the gate wiring 28 and the drain electrode 16b in the X direction. The gate wiring 28 electrically connects the gate bus bar 34 and the gate electrode 14b, and electrically connects the gate bus bar 34 and the gate electrode 14d to each other. In this way, the source wirings 22a and 22c shield the lines of electric force 64 (see FIG. 2) between the gate wiring 28 and the drain electrodes 16a and 16b. This makes it possible to suppress the gate/drain capacitance and suppress the deterioration of the characteristics without using the multilayer wiring as in the second comparative example. In this way, since the multilayer wiring is not used, the manufacturing process can be simplified. In addition, the warpage of the wafer can be suppressed. The gate wiring 28 is provided above the source electrode 12a. This allows the semiconductor device to be downsized as compared with the first comparative example.

The gate electrodes 14c and 14d, the drain electrode 16b, and the source wiring 22c may not be provided. The semiconductor device 100 can be downsized by not providing the gate electrodes 14c and 14d, the drain electrode 16b, and the source wiring 22c.

The − end (first end) of the gate wiring 28 in the Y direction is connected to the center portion of the connection wiring 29b in the X direction. Thus, the gate potential can be supplied to the gate electrodes 14b and 14d through the gate wiring 28 and the connection wiring 29b. In the first embodiment, the + end (second end) of the gate wiring 28 in the Y direction is connected to the central portion of the connection wiring 29a in the X direction. The gate electrodes 14a and 14b may be directly connected to the gate bus bar 34, and the + end (second end) of the gate wiring 28 in the Y direction may be directly connected to the gate bus bar 34.

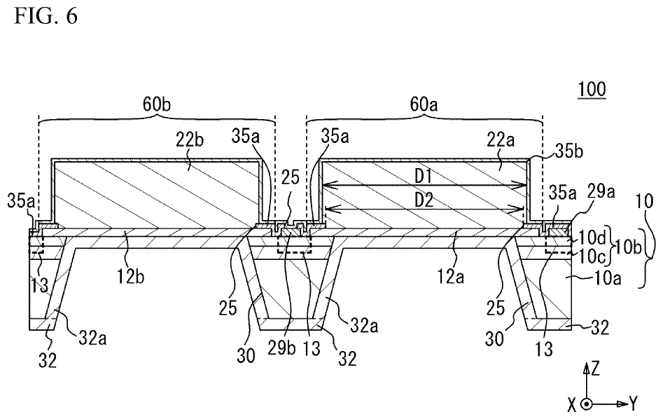

The source wirings 22a and 22c are wirings for reducing the current density flowing in the Y direction of the source electrode 12a. Therefore, the source wirings 22a and 22c are brought into contact with the source electrode 12a through the respective openings 25. When an area where the source wiring 22a and the source electrode 12a are in contact with each other is small, the effect of suppressing the current density flowing in the Y direction of the source electrode 12a is reduced. From this viewpoint, as illustrated in FIG. 6, a maximum width in the Y direction of the region where each of the source wirings 22a and 22c overlaps the source electrode 12a when viewed from the Z direction is defined as D1, and a maximum width in the Y direction of the region where each of the source wirings 22a and 22c is in contact with the source electrode 12a is defined as D2. In this case, the maximum width D2 is at least ½ times, at least ¾ times, or at least ⅘ times the maximum width D1. The maximum width D2 is less than or equal to 1 times the maximum width D1. The area of each of the regions where the source lines 22a and 22c are in contact with the source electrode 12a is at least ¼ times, at least ½ times, and at least ¾ times the area of each of the regions where each of the source wirings 22a and 22c overlaps with the source electrode 12a when viewed from the Z direction.

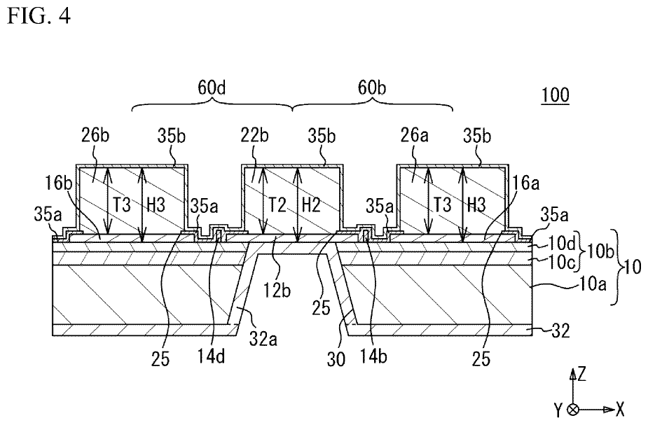

As illustrated in FIGS. 2 and 4, the heights of the upper surfaces of the source wirings 22a and 22c, the upper surface of the source wiring 22b, and the upper surfaces of the drain wirings 26a and 26b are respectively defined as H1, H2, and H3, with respect to the upper surface of the substrate 10. The height of the upper surface of the gate wiring 28 with respect to the upper surface of the substrate 10 is defined as H4. The thicknesses of the source wirings 22a and 22c are defined as T1, the thickness of the source wiring 22b is defined as T2, and the thicknesses of the drain wirings 26a and 26b are defined as T3.

At this time, the height H4 is smaller than the height H1. As a result, the lines of electric force between the gate wiring 28 and the drain electrodes 16a and 26a are shielded from the source wiring 22a, and the lines of electric force between the gate wiring 28, and the drain electrode 16b and the drain wiring 26b are shielded from the source wiring 22c. Therefore, the gate/drain capacitance can be further suppressed. The height H4 is, for example, 0.9 times or less and 0.8 times or less the height H1. From the viewpoint of reducing the resistance of the gate wiring 28, the height H4 is, for example, 0.2 times or more the height H1. Even if the height H4 is higher than the height H1, the gate/drain capacitance can be suppressed.

The source wiring 22b is a wiring for reducing the current density flowing in the Y direction of the source electrode 12b. The drain wirings 26a and 26b are wirings for reducing the current density flowing in the Y direction of the drain electrodes 16a and 16b, respectively. As illustrated in FIGS. 12A and 13A, the source wirings 22a to 22c and the drain wirings 26a and 26b are formed simultaneously. This can reduce the number of manufacturing steps compared to the case where the guard metal layers 23a and 23b are formed separately from the source wiring and the drain wiring as in the second comparative example. When the semiconductor device is manufactured in this manner, thicknesses T2 and T3 are equal to thickness T1. The height H2 is equal to the height Hl and the height H3 is equal to the height H1. The fact that the thicknesses T2 and T3 are equal (substantially equal) to the thickness T1 allows a manufacturing error, and for example, |T2−T1|/T1 and |T3−T1|/T1 may be 0.1 times or less.

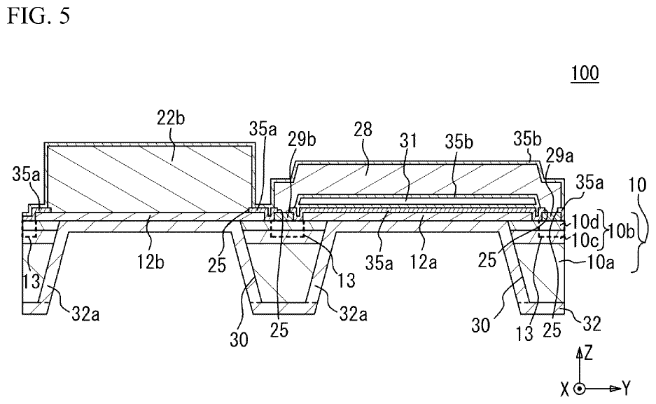

In FIG. 5, the insulating film 35a (inorganic insulating film) is provided on the source electrode 12a. The gate wiring 28 must not be in contact with the source electrode 12a, but for example, it may be in contact with the insulating film 35a on the source electrode 12a. However, when the gate wiring 28 is in contact with the insulating film 35a, the gate-source capacitance between the gate wiring 28 and the source electrode 12a increases. Therefore, the space 31 as the air gap is provided between the insulating film 35a and the gate wiring 28. This makes it possible to reduce the gate-source capacitance and suppress the deterioration of the characteristics.

### First Modification of First Embodiment

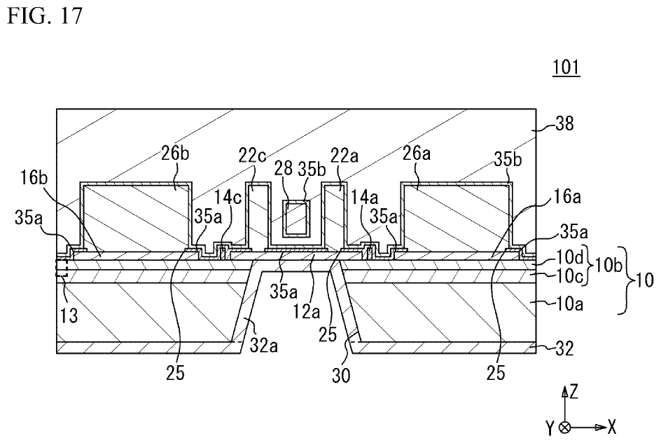

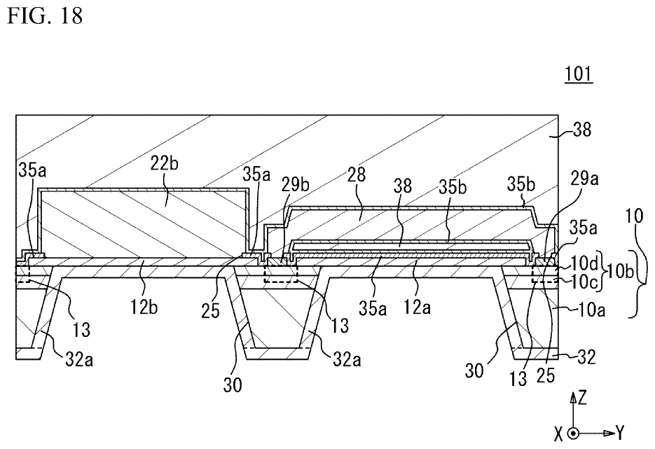

FIGS. 17 and 18 are cross-sectional views of a semiconductor device according to a first modification of the first embodiment. FIG. 17 is a view corresponding to the A-A cross section of FIG. 1, and FIG. 18 is a view corresponding to the D-D cross section of FIG. 1.

As illustrated in FIGS. 17 and 18, in a semiconductor device 101 of the first modification of the first embodiment, an organic insulating film 38 is provided so as to cover the insulating film 35b. The organic insulating film 38 is also provided between the gate wiring 28 and the insulating film 35a. The organic insulating film 38 is made of, for example, polyimide resin or BCB (Benzocyclobutane). The other configurations of the first modification of the first embodiment are the same as those of the first embodiment, and the description thereof is omitted.

The organic insulating film 38 is provided between the insulating film 35a and the gate wiring 28. In this case, the distance between the gate wiring 28 and the source electrode 12a can be increased, and therefore the gate-source capacitance can be reduced. The organic insulating film 38 may be a molding resin (for example, an epoxy resin) used for sealing. In order to reduce the gate-source capacitance, the relative dielectric constant of the organic insulating film 38 may be made lower than those of the insulating films 35a and 35b.

### Second Modification of First Embodiment

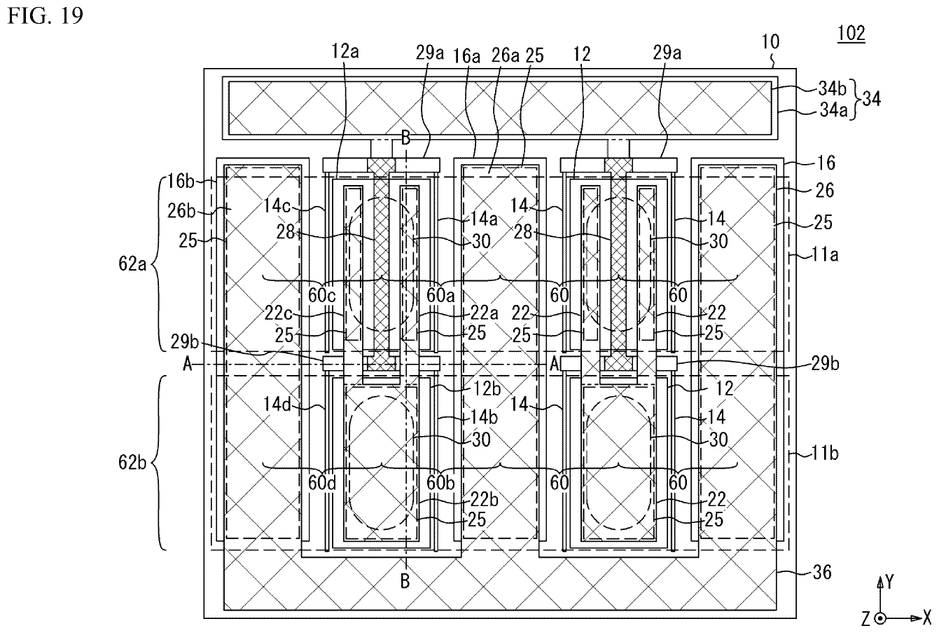

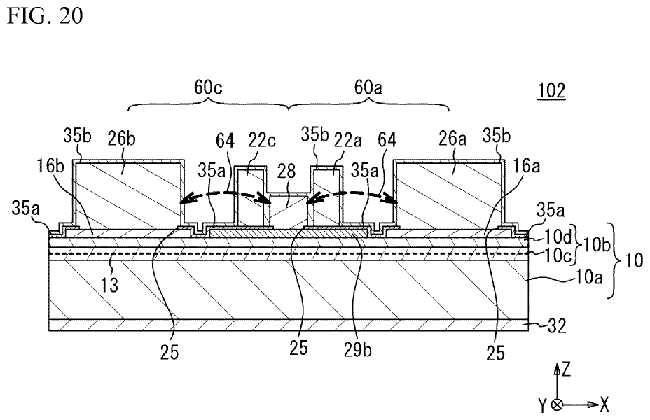

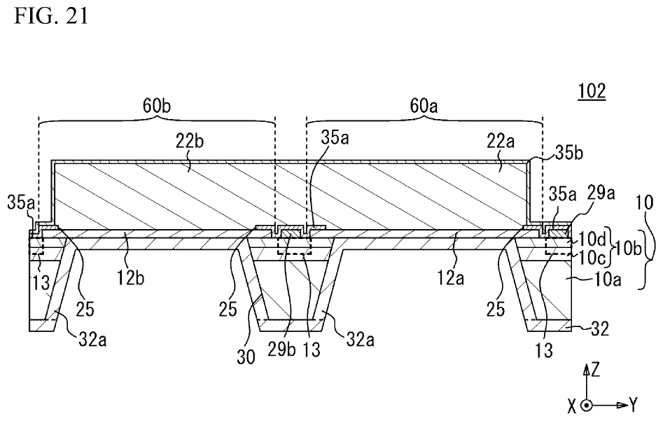

FIG. 19 is a plan view of a semiconductor device according to a second modification of the first embodiment. FIGS. 20 and 21 are cross-sectional views taken along the line A-A and line B-B in FIG. 19, respectively. As illustrated in FIGS. 19 to 21, in a semiconductor device 102 of the second modification of the first embodiment, the source wirings 22a and 22c extend in the − direction in the Y direction and are connected to the source wiring 22b. The insulating film 35a is provided between the source wirings 22a and 22c and the connection wiring 29b, and the source wirings 22a and 22c and the connection wiring 29b are not in contact with each other. The source wirings 22a and 22c are provided between the gate wiring 28 on the connection wiring 29b and the drain wirings 26a and 26b, respectively. The other configurations of the second modification of the first embodiment are the same as those of the first embodiment, and the description thereof is omitted.

In the semiconductor device 100 of the first embodiment, in a region between the FET groups 62a and 62b, the source wirings 22a and 22b are not provided between the gate wiring 28 and the drain wirings 26a and 26b, respectively. This increases the gate/drain capacitance. In the semiconductor device 102 of the second modification of the first embodiment, the source wirings 22a and 22c intersect the connection wiring 29b in a non-contact manner and are connected to the source wiring 22b. Thus, in the region between the FET groups 62a and 62b, the source wirings 22a and 22c shield the lines of electric force 64 (see FIG. 20) between the gate wiring 28 and the drain wirings 26a and 26b, respectively. Therefore, the gate/drain capacitance can be further suppressed.

The source wirings 22a and 22c may be provided on the insulating film 35a with a space therebetween, as in the case of the gate wiring 28 on the source electrode 12a. When the space is provided between the source wirings 22a and 22c and the insulating film 35a, the effect of shielding the lines of electric force between the gate wiring 28 and the drain wirings 26a and 26b is reduced. Therefore, the source wirings 22a and 22c may be in contact with the insulating film 35a.

### Third Modification of First Embodiment

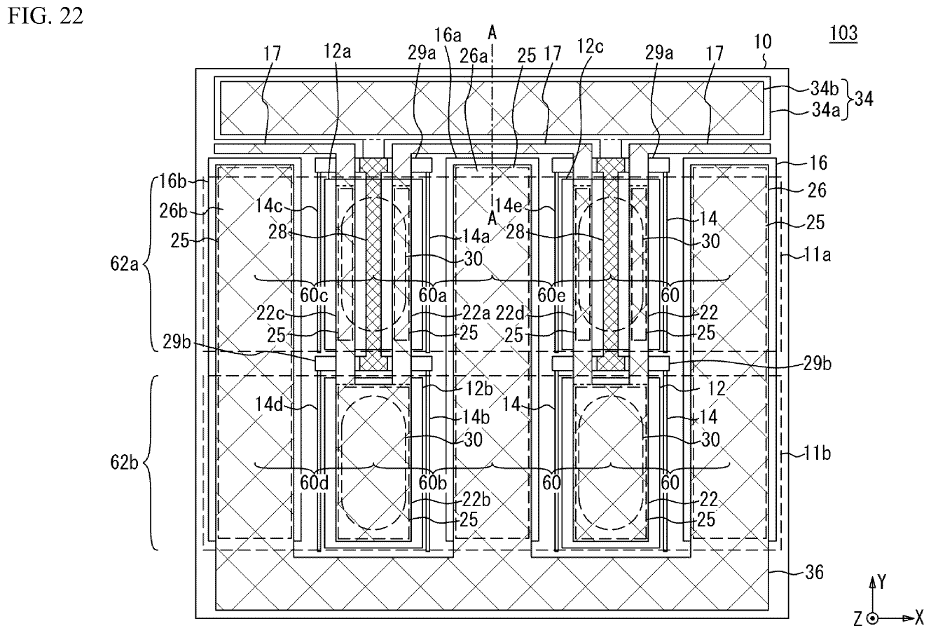

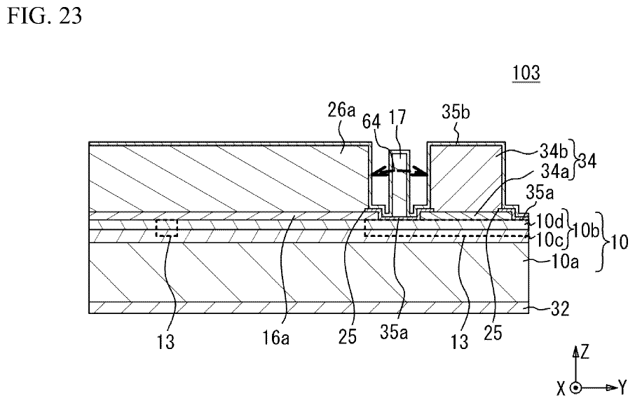

FIG. 22 is a plan view of a semiconductor device according to a third modification of the first embodiment. FIG. 23 is a cross-sectional view taken along the line A-A in FIG. 22. As illustrated in FIGS. 22 and 23, in a semiconductor device 103 of the third modification of the first embodiment, a unit FET 60e (fifth unit FET) includes the source electrode 12c (third source electrode), a gate electrode 14e (fifth gate electrode), and the drain electrode 16a. A source wiring 22d (fourth source wiring) is provided on the source electrode 12c, and the source wiring 22d is in electrical contact with the source electrode 12c. A connection wiring 17 (second connection wiring) electrically connects the source wirings 22a and 22d interposing the drain wiring 26a to each other, and is provided between the gate bus bar 34 and the drain wiring 26a in the Y direction. The connection wiring 17 is provided in contact with the insulating film 35a. The other configurations of the third modification of the first embodiment are the same as those of the second modification of the first embodiment, and the description thereof is omitted.

In the semiconductor devices 100 and 102 of the first embodiment and the second modification, the gate-drain capacitance is generated between the drain wiring 26a and the gate bus bar 34. In the semiconductor device 103 of the third modification of the first embodiment, the connection wiring 17 electrically connected to and short-circuited with the source wirings 22a and 22d is provided between the gate bus bar 34 and the drain wiring 26a. As a result, the connection wiring 17 shields the lines of electric force 64 (see FIG. 23) between the gate bus bar 34 and the drain wiring 26a. Therefore, the gate/drain capacitance can be suppressed. In addition, the potentials of the source wirings 22a and 22d can be stabilized.

In the second and third modifications of the first embodiment, even if the via hole 30 is not provided in the source electrode 12a, the source potential may be supplied from the source electrode 12b through the source wirings 22a and 22c. Further, the source pad may be provided outside the active region 11b without providing the via hole 30 in the source electrode 12b.

### Fourth Modification of First Embodiment 1

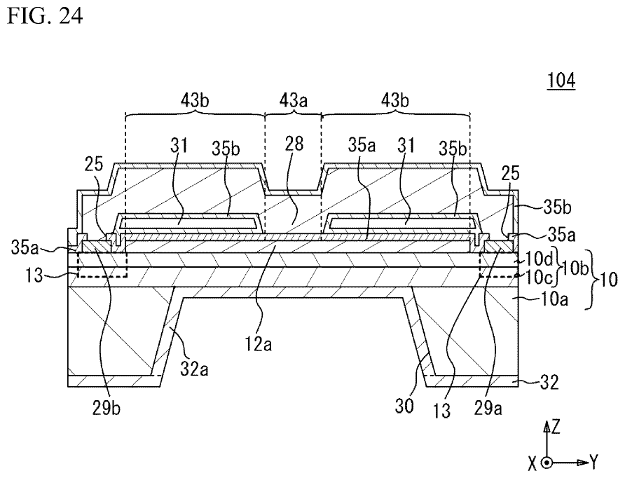

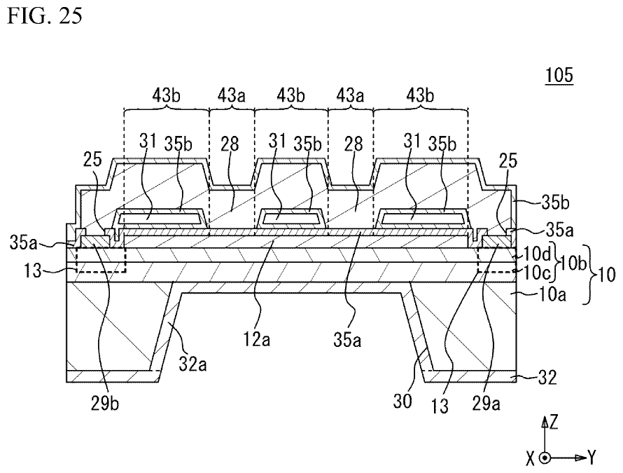

FIGS. 24 and 25 are cross-sectional views of a semiconductor device according to a fourth modification of the first embodiment. FIGS. 24 and 25 correspond to cross sections of the gate wiring 28 in the X direction. As illustrated in FIGS. 24 and 25, in semiconductor devices 104 and 105 of the fourth modification of the first embodiment, the gate wiring 28 is in contact with the insulating film 35a at a portion 43a of the center of the source electrode 12a in the Y direction. In FIG. 24, the single portion 43a is provided, and in FIG. 25, two portions 43a are provided. At portions 43b sandwiching the portion 43a in the Y direction, the gate wiring 28 interposes the space 31 between the gate wiring 28 and the insulating film 35a. The other configurations of the fourth modification of the first embodiment are the same as those of the first embodiment and the first to third modifications thereof, and the description thereof is omitted.

When the gate wiring 28 is provided at a long portion with the space 31 interposed between the insulating film 35a and the gate wiring 28, the shape of the gate wiring 28 becomes unstable. In such a case, in the portions 43a (first portion) in the Y direction of the region where the gate wiring 28 overlaps with the source electrodes 12a as viewed from the Z direction, the gate wiring 28 is in contact with the insulating film 35a without interposing the space 31 (for example, the organic insulating film and the air gap). In the portions 43b (second portion) interposing the portion 43a in the Y direction of the region where the gate wiring 28 overlaps the source electrode 12a, the gate wiring 28 and the insulating film 35a interpose the space 31 (for example, the organic insulating film or the air gap). This makes it possible to stabilize the shape of the gate wiring 28.

The total width of the portions 43a in the Y direction is, for example, equal to or more than 1/20 times and equal to or less than ½ times the width of the source electrode 12a in the Y direction.

### Fifth Modification of First Embodiment

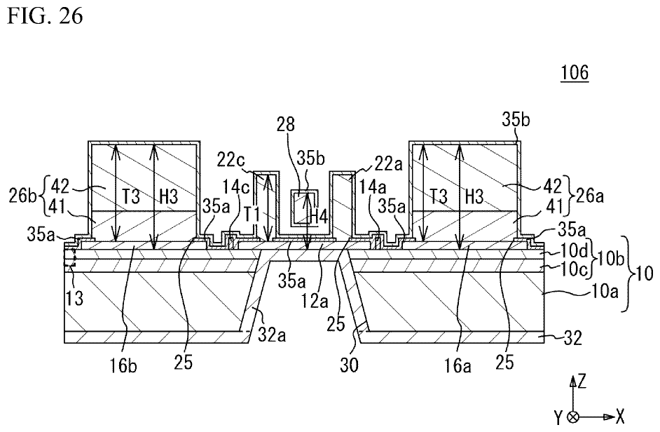

FIG. 26 is a cross-sectional view of a semiconductor device according to a fifth modification of the first embodiment. FIG. 26 is a view corresponding to the A-A cross section of FIG. 1. As illustrated in FIG. 26, in a semiconductor device 106 of the fifth modification of the first embodiment, each of the drain wirings 26a and 26b includes the plating layer 41 and the plating layer 42 provided on the plating layer 41. The plating layer 41 is formed simultaneously with the plating layer 41 of the gate wiring 28 (see FIGS. 10A and 10B), and the plating layer 42 is formed simultaneously with the plating layer 42 of the source wirings 22a to 22c (see FIGS. 12A and 12B). As a result, the thickness of each of the drain wirings 26a and 26b is substantially equal to the total thicknesses of the source wiring 22a and the gate wiring 28.

A current can be supplied to the source electrodes 12a and 12b by the metal layers 32 and 32a via the via holes 30 in addition to the source wirings 22a to 22c. On the other hand, a current is supplied to the drain electrodes 16a and 16b only from the drain wirings 26a and 26b. Therefore, by making the drain wirings 26a and 26b thicker than the source wirings 22a to 22c, a larger drain current can be flown, and a large power operation can be performed. In addition, the drain resistance can be reduced. In this way, the height H3 of the upper surfaces of the drain wirings 26a and 26b with respect to the upper surface of the substrate 10 may be equal to or more than the height H1 of the upper surfaces of the source wirings 22a to 22c with respect to the upper surface of the substrate 10. From the viewpoint of reducing the gate/drain capacitance, all straight lines extending from the gate wiring 28 to the drain wirings 26a and 26b may be hidden by the source wirings 22a and 22c. The other configurations of the fifth modification of the first embodiment are the same as those of the first embodiment, and the description thereof is omitted.

### Sixth Modification of First Embodiment

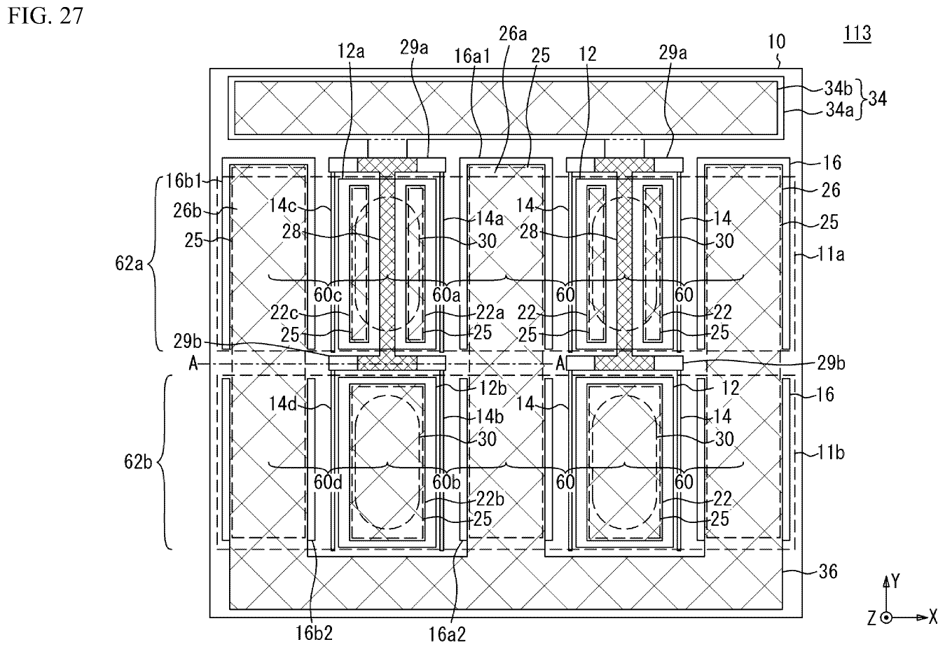

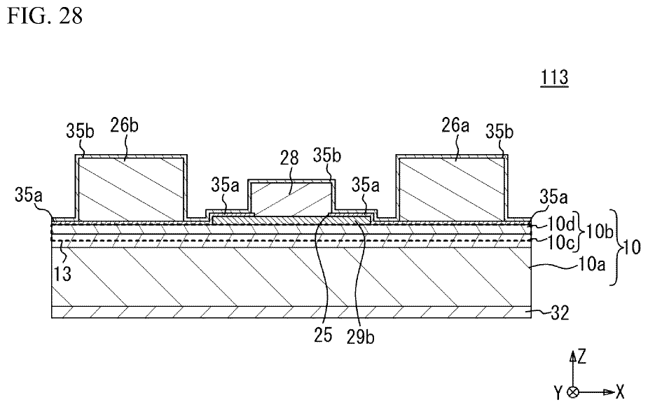

FIG. 27 is a plan view of a semiconductor device according to a sixth modification of the first embodiment. FIG. 28 is a cross-sectional view taken along the line A-A in FIG. 27. As illustrated in FIGS. 27 and 28, in a semiconductor device 113 of the sixth modification of the first embodiment, the drain electrodes 16a and 16b are not provided between the active regions 11a and 11b. Drain electrodes 16a1 and 16b1 are provided in the active region 11a, and drain electrodes 16a2 and 16b2 are provided in the active region 11b. The drain electrodes 16a1 and 16a2 are electrically connected by the drain wiring 26a, and the drain electrodes 16b1 and 16b2 are electrically connected by the drain wiring 26b. The drain wirings 26a and 26b are provided on the insulating film 35a between the active regions 11a and 11b. The other configurations of the sixth modification of the first embodiment are the same as those of the first embodiment, and the description thereof is omitted. In the embodiments other than the first embodiment and the modifications thereof, the drain electrode may not be provided between the active regions 11a and 11b.

### Second Embodiment

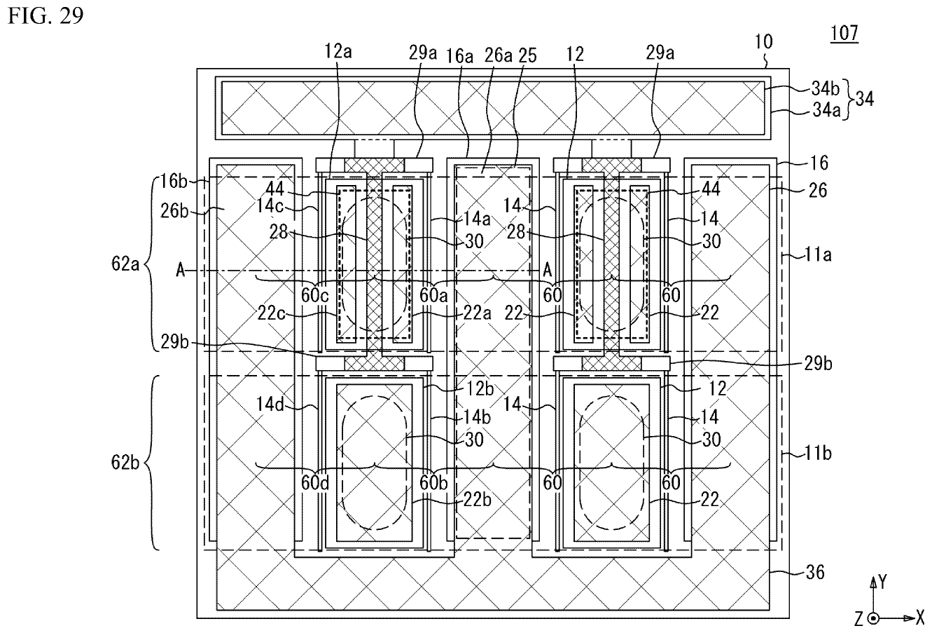

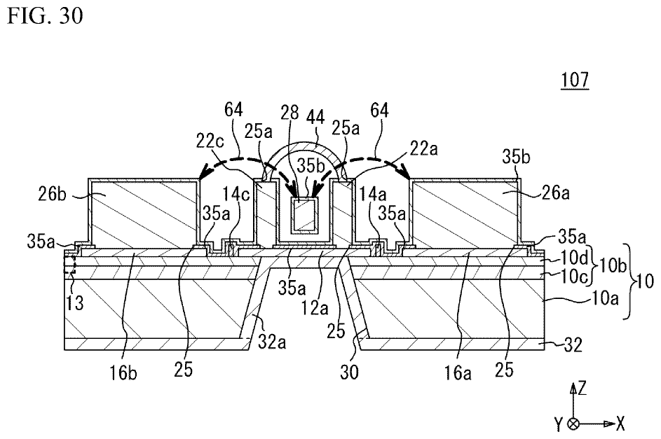

FIG. 29 is a plan view of a semiconductor device according to a second embodiment. FIG. 30 is a cross-sectional view taken along the line A-A in FIG. 29. In FIG. 29, a part of the openings 25 is not illustrated. As illustrated in FIGS. 29 and 30, in a semiconductor device 107 of the second embodiment, a guard metal layer 44 is provided so as to cover a portion above the gate wiring 28. A first end of the guard metal layer 44 is connected to the upper surface of the source wiring 22a, and a second end of the guard metal layer 44 is connected to the upper surface of the source wiring 22c. The guard metal layer 44 is, for example, a gold layer, a copper layer, or an aluminum layer. The other configurations of the second embodiment are the same as those of the first embodiment, and the description thereof is omitted.

### Manufacturing Method of Second Embodiment

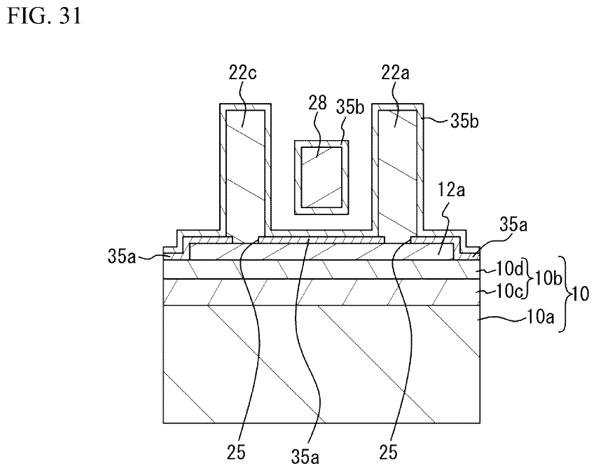

FIGS. 31 to 35 are cross-sectional views illustrating a method of manufacturing a semiconductor device according to the second embodiment. In FIGS. 31 to 35, the illustration of the via hole 30 and the metal layers 32 and 32a is not omitted.

As illustrated in FIG. 31, the source wirings 22a and 22c are provided on the source electrode 12a in contact with each other, as in FIG. 14A. The gate wiring 28 is provided between the source wirings 22a and 22c on the source electrode 12a. The insulating film 35b is provided so as to surround the source wirings 22a and 22c and the gate wiring 28.

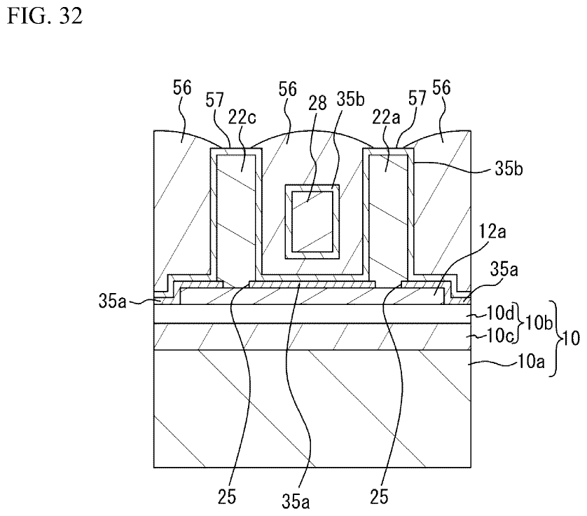

As illustrated in FIG. 32, a mask layer 56 is formed on the substrate 10. The mask layer 56 has openings 57 for exposing the insulating film 35b on the upper surfaces of the source wirings 22a and 22c. The mask layer 56 is, for example, a photoresist.

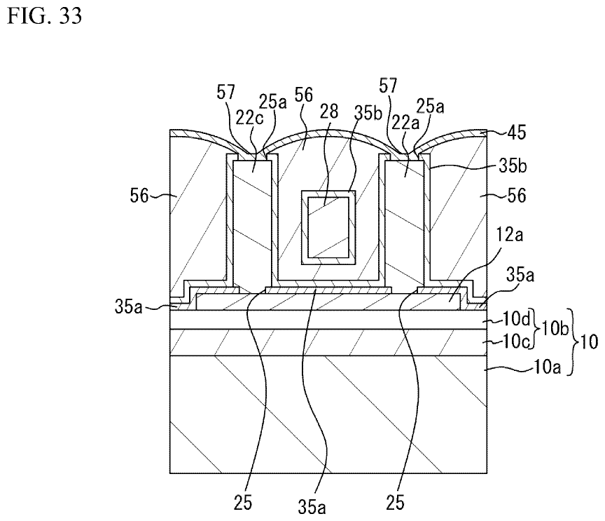

As illustrated in FIG. 33, openings 25a are formed in the insulating film 35b using the mask layer 56 as a mask. A seed layer 45 is formed on the openings 25a and the mask layer 56. The seed layer 45 is formed on the entire surface of the substrate 10 by, for example, sputtering. The seed layer 45 has, for example, an adhesion layer and a low resistance layer on the adhesion layer. The low resistance layer is a metal layer made of the same material as a plating layer 46 described later, for example.

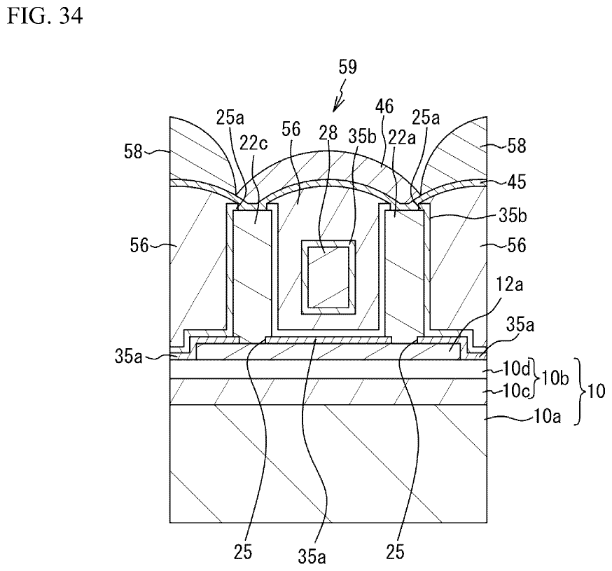

As illustrated in FIG. 34, a mask layer 58 is formed on the seed layer 45. The mask layer 58 has an opening 59 between the source lines 22a and 22c. The mask layer 58 is, for example, a photoresist. The plating layer 46 is formed in the opening 59 by electrolytic plating.

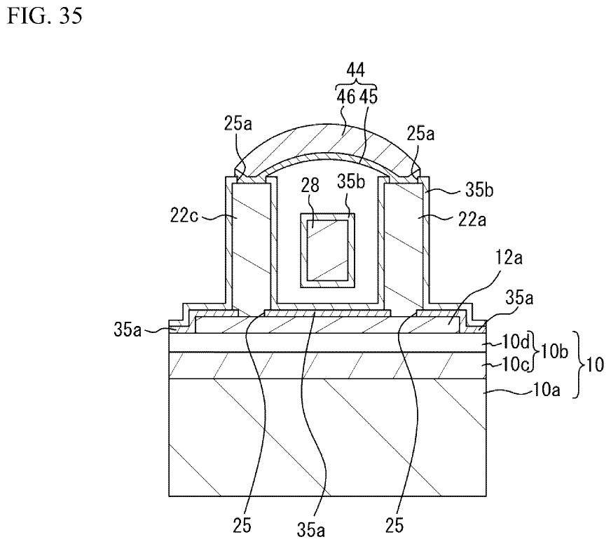

As illustrated in FIG. 35, the mask layer 58 is peeled off. The seed layer 45 is removed using the plating layer 46 as a mask. The mask layer 56 is removed. As a result, the guard metal layer 44 is formed from the seed layer 45 and the plating layer 46.

In the semiconductor device 100 of the first embodiment, a portion above the gate wiring 28 between the source wirings 22a and 22c is opened, as illustrated in FIG. 2. Therefore, the lines of electric force extend from the gate wiring 28 to the drain wirings 26a and 26b bypassing the source wirings 22a and 22c. This results in the gate-drain capacitance. In the semiconductor device 107 of the second embodiment, the guard metal layer 44 is provided above the gate wiring 28 in a non-contact manner with the gate wiring 28, and electrically connects the source wiring 22a and the source wiring 22c to each other. As a result, the guard metal layer 44 shields the lines of electric force 64 (see FIG. 30) between the gate wiring 28 and the drain wirings 26a and 26b. Therefore, the gate/drain capacitance can be further suppressed.

### First Modification of Second Embodiment

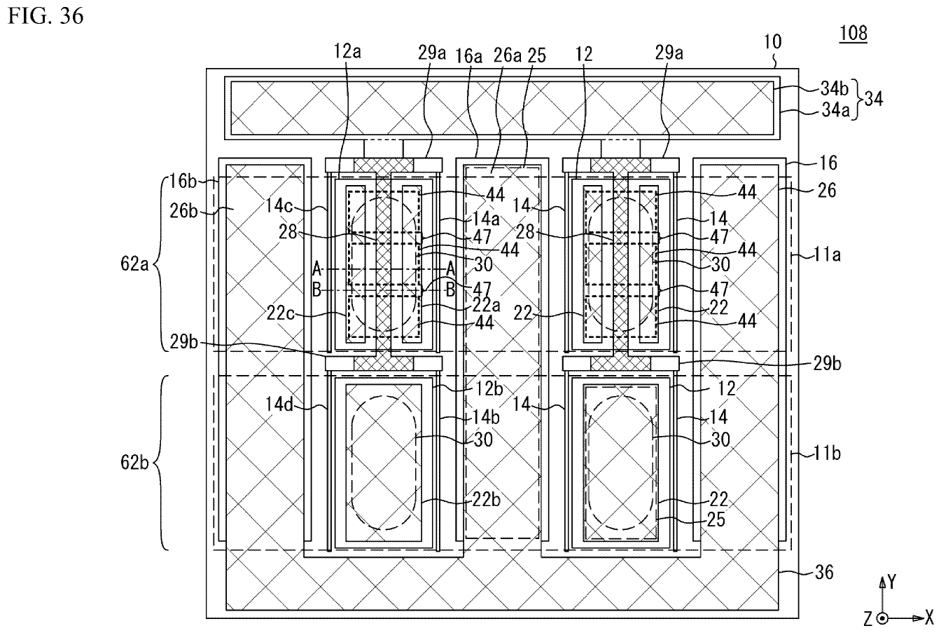

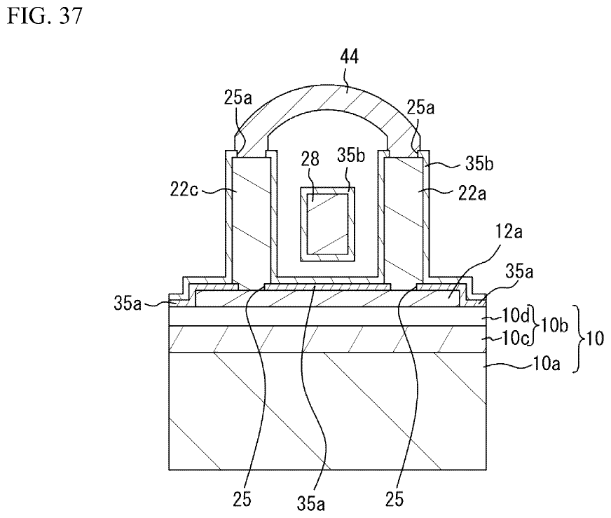

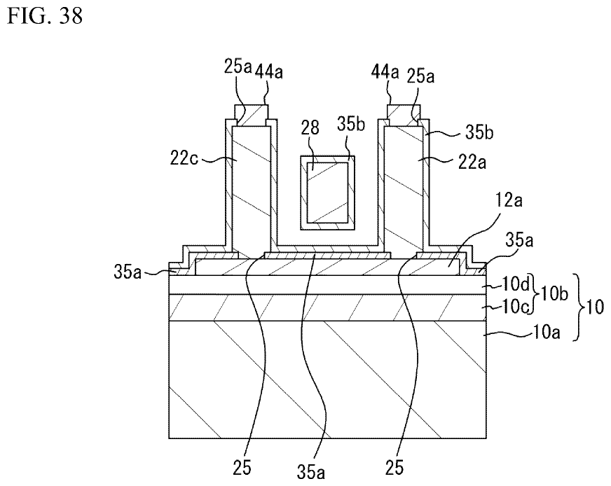

FIG. 36 is a plan view of a semiconductor device according to a first modification of the second embodiment. FIGS. 37 and 38 are cross-sectional views taken along the line A-A and the line B-B of FIG. 36, respectively. As illustrated in FIGS. 36 to 38, in a semiconductor device 108 of the first modification of the second embodiment, the plurality of guard metal layers 44 are provided above one gate wiring 28. Each of the plurality of guard metal layers 44 connects the source wirings 22a and 22c to each other. A part 44a of the guard metal layer 44 is provided between the plurality of guard metal layers 44, and air gaps 47 are provided above the gate wiring 28. The other configurations of the first modification of the second embodiment are the same as those of the second embodiment, and the description thereof is omitted.

In the semiconductor device 107 of the second embodiment in FIGS. 34 and 35, when the mask layer 56 under the guard metal layer 44 is peeled, the peeling liquid or the oxygen plasma for ashing may not reach under the central portion of the guard metal layer 44 in the Y direction. In this case, the mask layer 56 remains. In the semiconductor device 108 of the first modification of the second embodiment, the air gaps 47 are provided between the plurality of guard metal layers 44. This allows the peeling liquid to reach the mask layer 56 under the guard metal layer 44, and can suppress the mask layer 56 from remaining. From the viewpoint of shielding the lines of electric force, the area where the guard metal layer 44 overlaps the region between the source wirings 22a and 22c when viewed from the Z direction may be ½ or more or ¾ or more the area of the region between the source wirings 22a and 22c. The guard metal layer 44 as in the second embodiment and the modification thereof may be provided in the modification of the first embodiment.

### Third Embodiment

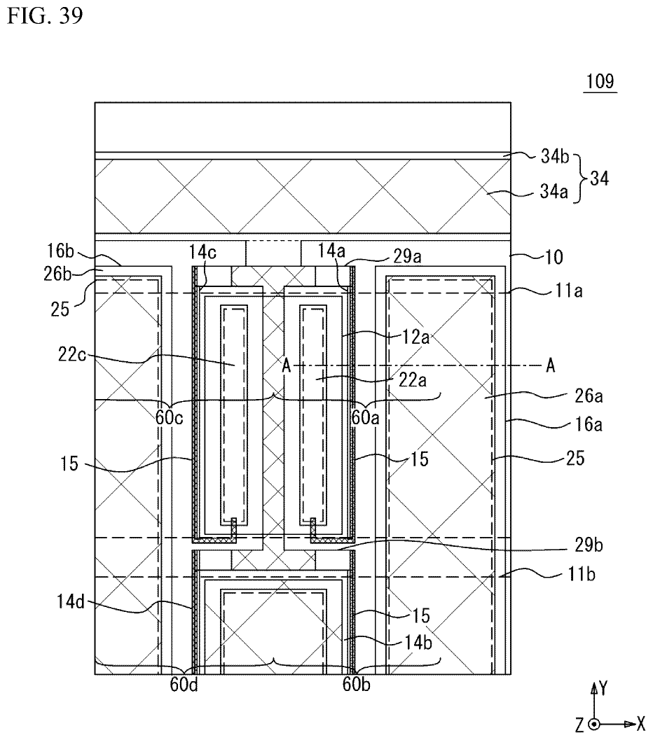

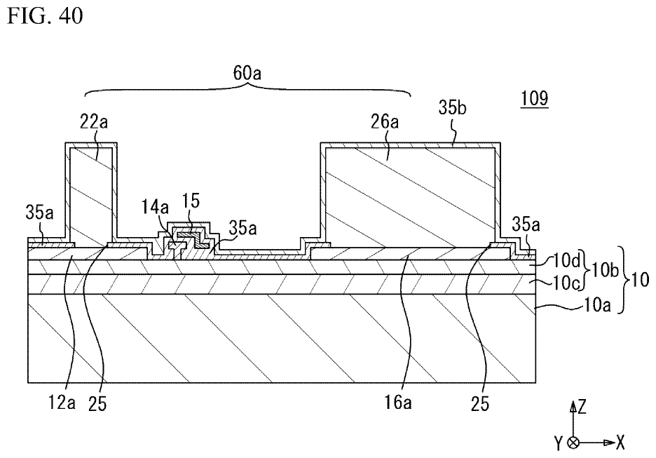

FIG. 39 is a plan view of a semiconductor device according to a third embodiment. FIG. 40 is a cross-sectional view taken along the line A-A of FIG. 39. In FIGS. 39 and 40, the illustration of the via hole 30 and the metal layers 32 and 32a is not omitted.

As illustrated in FIGS. 39 and 40, in a semiconductor device 109 of the third embodiment, the width of a portion of each of the gate electrodes 14a to 14d in the X direction far from the semiconductor layer 10b is wider than the width of a portion of each of the gate electrodes 14a to 14d in the X direction close to the semiconductor layer 10b. That is, the gate electrodes 14a to 14d are T-type or T-type gates. Field plates 15 are provided above the substrate 10 with the insulating film 35a interposed therebetween, between the gate electrode 14a and the drain electrode 16a, between the gate electrode 14b and the drain electrode 16a, between the gate electrode 14c and the drain electrode 16b, and between the gate electrode 14d and the drain electrode 16b, respectively. The field plates 15 are also provided on both sides of each of the connection wirings 29a and 29b in the X direction. This makes it possible to suppress the capacitances between the connection wirings 29a and 29b and the drain wirings 26a and 26b.

The field plates 15 are connected to the source wirings 22a and 22c at the − ends of the source wirings 22a and 22c in the Y direction, respectively. As a result, the field plates 15 are electrically connected to the source electrodes 12a, 12b, and 12c, and the reference potential is supplied. The field plates 15 may be connected to the source wirings 22a and 22c at the + ends or both of the − ends and the + ends of the source wirings 22a and 22c in the Y direction.

The field plates 15 can reduce electric field concentration in the semiconductor layer 10b between the gate electrode 14a and the drain electrode 16a, between the gate electrode 14b and the drain electrode 16a, between the gate electrode 14c and the drain electrode 16b, and between the gate electrode 14d and the drain electrode 16b. This makes it possible to suppress a current drift phenomenon. A part of the field plate 15 may be provided above each of the gate electrodes 14a to 14d. This makes it possible to suppress the gate/drain capacitance. The other configurations of a third embodiment are the same as those of the first embodiment, and the description thereof is omitted.

### First Modification of Third Embodiment

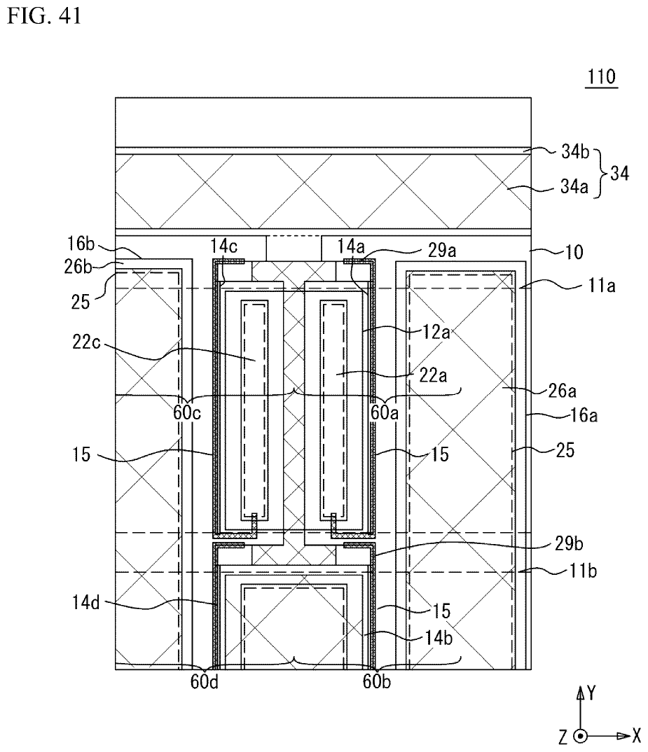

FIG. 41 is a plan view of a semiconductor device according to a first modification of the third embodiment. As illustrated in FIG. 41, in a semiconductor device 110 of the first modification of the third embodiment, the field plates 15 are provided on the + sides in the Y direction of the connection wirings 29a and 29b. This makes it possible to suppress the gate-drain capacitance between the connection wiring 29a and the drain wirings 26a and 26b, and between the connection wiring 29b and the drain wirings 26a and 26b. The other configurations of the first modification of the third embodiment are the same as those of the third embodiment, and the description thereof is omitted.

### Second Modification of Third Embodiment

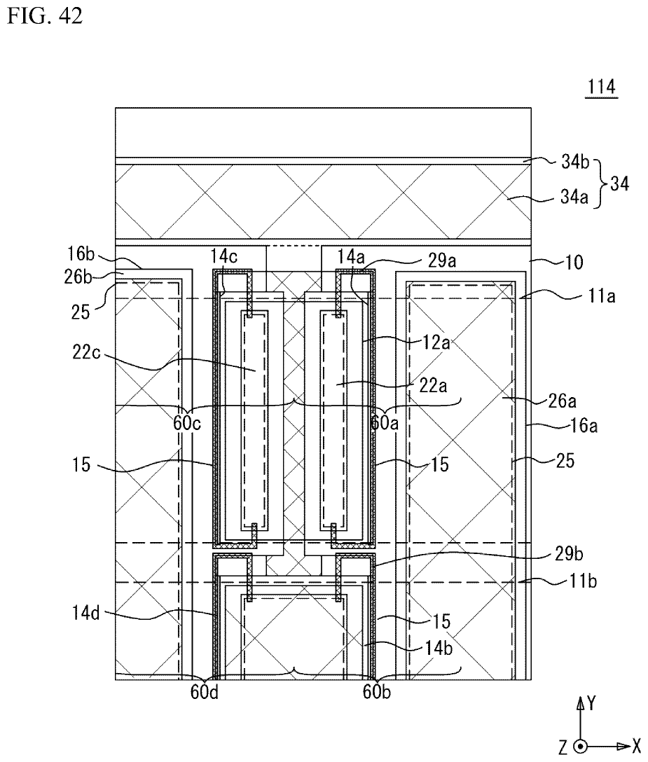

FIG. 42 is a plan view of a semiconductor device according to a second modification of the third embodiment. As illustrated in FIG. 42, in a semiconductor device 114 of the second modification of the third embodiment, the field plates 15 intersect portions above the connection wirings 29a and 29b in a non-contact manner, and are connected to the source wirings 22a and 22c at the + ends of the source wirings 22a and 22c in the Y direction. The other configurations of the second modification of the third embodiment are the same as those of the first modification of the third embodiment, and the description thereof is omitted. As in the second modification of the third embodiment, the field plates 15 may be connected to the source wirings 22a and 22c at both the + ends and the − ends of the source wirings 22a and 22c in the Y direction. This makes it possible to stably supply the reference potential to the entire field plates 15. The field plates 15 may be connected to the source wirings 22a and 22c at the + ends of the source wirings 22a and 22c in the Y direction.

### Third Modification of Third Embodiment

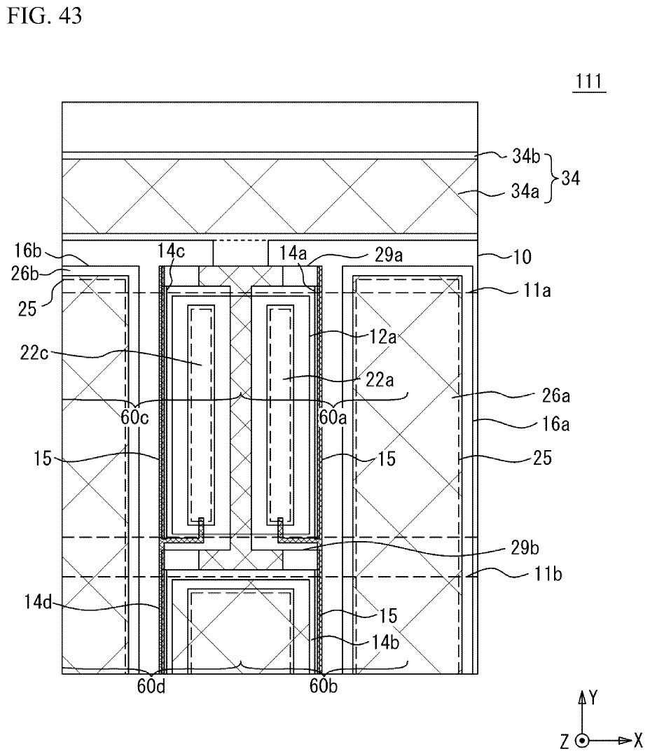

FIG. 43 is a plan view of a semiconductor device according to a third modification of the third embodiment. As illustrated in FIG. 43, in a semiconductor device 111 of the third modification of the third embodiment, the field plate 15 of the unit FET 60a and the field plate 15 of the unit FET 60b are provided continuously. The field plate 15 of the unit FET 60c and the field plate 15 of the unit FET 60d are provided continuously. This makes it possible to suppress the gate-drain capacitances between the connection wiring 29a and the drain wirings 26a and 26b, and between the connection wiring 29b and the drain wirings 26a and 26b. The other configurations of the third modification of the third embodiment are the same as those of the third embodiment, and the description thereof is omitted.

The field plate 15 may be provided in the first and second embodiments and the modification thereof.

### Fourth Embodiment

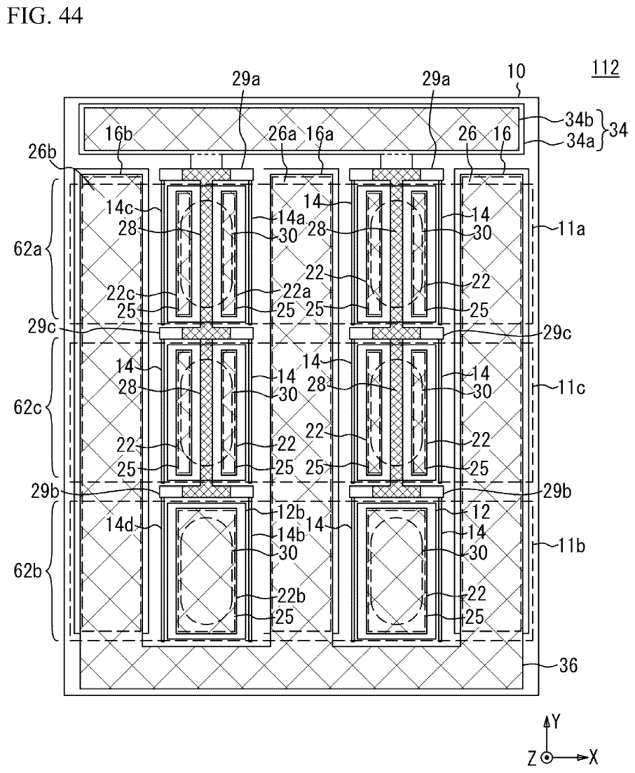

FIG. 44 is a plan view of a semiconductor device according to a fourth embodiment. As illustrated in FIG. 44, in a semiconductor device 112 of the fourth embodiment, an active region 11c is provided between the active regions 11a and 11b. The active region 11c is provided with an FET group 62c. A connection wiring 29c is provided between the FET groups 62a and 62c. The connection wiring 29b is provided between the FET groups 62c and 62b. The − end of the gate wiring 28 of the FET group 62a in the Y direction and the + end of the gate wiring 28 of the FET group 62c in the Y direction are connected to the connection wiring 29c. The − end of the gate wiring 28 of the FET group 62c in the Y direction is connected to the connection wiring 29b. The other configurations of the fourth embodiment are the same as those of the first embodiment, and the description thereof is omitted.

As in the fourth embodiment, three FET groups 62a to 62c may be provided in the Y direction. This can further reduce the gate resistance. Four or more FET groups may be provided in the Y direction. In the first to third embodiments and the modified examples thereof, three or more FET groups may be provided.

Although the first to fourth embodiments and the modified embodiments thereof have been described with respect to the example in which four unit FETs are arranged in the X direction, the number of unit FETs in the X direction can be freely designed.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
a first unit FET that is provided on the substrate, and includes a first source electrode extending in a first direction, a first drain electrode extending in the first direction, and a first gate electrode extending in the first direction and provided between the first source electrode and the first drain electrode in a second direction intersecting the first direction;
a second unit FET that is provided on the substrate in the first direction with respect to the first unit FET, and includes a second source electrode extending in the first direction, a second drain electrode extending in the first direction, and a second gate electrode extending in the first direction and provided between the second source electrode and the second drain electrode in the second direction;
a first source wiring that extends in the first direction, is provided on the first source electrode, and is in electrical contact with the first source electrode;
a gate bus bar that is electrically connected to the first gate electrode, and is provided so as to interpose the first gate electrode between the gate bus bar and the second gate electrode in the first direction; and
a gate wiring that is provided above the first source electrode in non-contact with the first source electrode, interposes the first source wiring between the gate wiring and the first drain electrode in the second direction, extends in the first direction, and electrically connects the gate bus bar and the second gate electrode to each other;
wherein a maximum width in the first direction of a region where the first source wiring is in contact with the first source electrode is ½ times or more a maximum width in the first direction of a region where the first source wiring overlaps the first source electrode when viewed from a thickness direction of the substrate.

2. The semiconductor device according to claim 1, wherein
a height of an upper surface of the gate wiring from an upper surface of the substrate is smaller than a height of an upper surface of the first source wiring from the upper surface of the substrate.

3. The semiconductor device according to claim 1, further comprising:
a first drain wiring that extends in the first direction, is provided on the first drain electrode, and is in electrical contact with the first drain electrode;
wherein a thickness of the first source wiring is equal to or less than a thickness of the first drain wiring.

4. The semiconductor device according to claim 1, further comprising:
a second source wiring that extends in the first direction, is provided on the second source electrode, and is in electrical contact with the second source electrode;
wherein a thickness of the first source wiring is equal to a thickness of the second source wiring.

5. The semiconductor device according to claim 1, further comprising:
an inorganic insulating film provided on the first source electrode; and
an organic insulating film or an air gap provided between the inorganic insulating film and the gate wiring.

6. The semiconductor device according to claim 5, wherein
in a first portion which is a part in the first direction of a region where the gate wiring overlaps with the first source electrode in the first direction when viewed from the thickness direction of the substrate, the gate wiring is in contact with the inorganic insulating film without interposing the organic insulating film or the air gap therebetween, and
in second portions which interpose the first portion in the first direction of the region, the gate wiring and the inorganic insulating film interpose the organic insulating film or the air gap.

7. The semiconductor device according to claim 1, further comprising:
a second source wiring that extends in the first direction, is provided on the second source electrode, and is in electrical contact with the second source electrode; and
a first connection wiring that extends in the second direction, is interposed between the first source electrode and the second source electrode in the first direction, and electrically connects the gate wiring and the second gate electrode to each other;
wherein the first source wiring intersects the first connection wiring in a non-contact manner and is connected to the second source wiring.

8. The semiconductor device according to claim 1, further comprising:
a third unit FET that is provided on the substrate, and includes the first source electrode, a third drain electrode extending in the first direction and interposing the first source electrode between the third drain electrode and the first drain electrode in the second direction, and a third gate electrode extending in the first direction and provided between the first source electrode and the third drain electrode in the second direction;
a fourth unit FET that is provided on the substrate in the first direction with respect to the third unit FET, and includes the second source electrode, a fourth drain electrode extending in the first direction and interposing the second source electrode between the fourth drain electrode and the second drain electrode in the second direction, and a fourth gate electrode extending in the first direction and provided between the second source electrode and the fourth drain electrode in the second direction; and
a third source wiring that extends in the first direction, is provided on the first source electrode, interposes the gate wiring between the third source wiring and the first source wiring in the second direction, and is in electrical contact with the first source electrode;
wherein a maximum width in the first direction of a region where the third source wiring is in contact with the first source electrode is ½ times or more a maximum width in the first direction of a region where the third source wiring overlaps the first source electrode when viewed from the thickness direction of the substrate.

9. The semiconductor device according to claim 8, further comprising:
a first connection wiring that is interposed between the first source electrode and the second source electrode in the first direction and electrically connects the second gate electrode and the fourth gate electrode to each other;
wherein an end of the gate wiring is connected to a central portion of the first connection wiring in the second direction.

10. The semiconductor device according to claim 8, further comprising:
a guard metal layer that is provided above the gate wiring in non-contact with the gate wiring, and connects the first source wiring and the third source wiring to each other.

11. The semiconductor device according to claim 1, further comprising:
a fifth unit FET that is provided on the substrate, and includes a third source electrode extending in the first direction and interposing the first drain electrode between the third source electrode and the first source electrode in the second direction, the first drain electrode, and a fifth gate electrode extending in the first direction and provided between the third source electrode and the first drain electrode in the second direction;
a fourth source wiring that extends in the first direction, is provided on the third source electrode, and is in electrical contact with the third source electrode; and
a second connection wiring that is provided between the first drain electrode and the gate bus bar in the first direction and electrically connects the first source wiring and the fourth source wiring to each other.

12. A method of manufacturing a semiconductor device comprising:
forming a first unit FET and a second unit FET on a substrate,
the first unit FET including: a first source electrode extending in a first direction; a first drain electrode extending in the first direction; and a first gate electrode extending in the first direction and provided between the first source electrode and the first drain electrode in a second direction intersecting the first direction,
the second unit FET including: a second source electrode extending in the first direction, a second drain electrode extending in the first direction, and a second gate electrode extending in the first direction and provided between the second source electrode and the second drain electrode in the second direction, the second unit FET being positioned in the first direction with respect to the first unit FET;
simultaneously forming a first source wiring extending in the first direction, provided on the first source electrode, and being in electrical contact with the first source electrode, a second source wiring extending in the first direction, provided on the second source electrode, and being in electrical contact with the second source electrode, and a first drain wiring extending in the first direction, provided on the first drain electrode, and being in electrical contact with the first drain electrode; and
forming a gate wiring that is provided above the first source electrode in non-contact with the first source electrode, interposes the first source wiring between the gate wiring and the first drain electrode in the second direction, extends in the first direction, and electrically connects a gate bus bar and the second gate electrode to each other.
